(19) United States
(12) Patent Application Publication
(10) Pub. No.: US 2014/0009905 A1
(43) Pub. Date: Jan. 9, 2014

(54) FLUORESCENT SUBSTRATE, DISPLAY APPARATUS, AND LIGHTING APPARATUS

(71) Applicants: Yuhki Kobayashi, Osaka-shi (JP); Mitsuhiro Koden, Osaka-shi (JP); Yoshimasa Fujita, Osaka-shi (JP); Hisanori Bessho, Osaka-shi (JP)

(72) Inventors: Yuhki Kobayashi, Osaka-shi (JP); Mitsuhiro Koden, Osaka-shi (JP); Yoshimasa Fujita, Osaka-shi (JP); Hisanori Bessho, Osaka-shi (JP)

(73) Assignee: Sharp Kabushiki Kaisha, Osaka (JP)

(21) Appl. No.: 13/994,126

(22) PCT Filed: Dec. 13, 2011
(86) PCT No.: PCT/JP11/78763

§ 371 Date: Sep. 27, 2013

(30) Foreign Application Priority Data
Dec. 16, 2010 (JP) 2010-280647

(51) Int. Cl. F21V 9/16

(52) U.S. Cl. CPC F21V 9/16
USPC 362/84

(57) ABSTRACT

A fluorescent substrate includes a substrate, a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, and reflective portions, which face the incident surface and side surfaces of the fluorescent layer in contact with the incident surface. The reflective portions include a first reflective portion that reflects the excitation light and the fluorescence and a second reflective portion disposed on at least part of the incident surface, the second reflective portion allowing at least light having a peak wavelength of the excitation light to pass through and reflecting at least light having a peak wavelength of the fluorescence.

### TECHNICAL FIELD

The present invention relates to a fluorescent substrate, a display apparatus, and a lighting apparatus.

The present application claims the priority of Japanese Patent Application No. 2010-280647 filed on Dec. 16, 2010 in Japan, which is incorporated herein by reference in its entirety.

### BACKGROUND ART

Fluorescent substrates are known to utilize light emitted from an organic EL device as excitation light and absorb the excitation light to emit fluorescence having a different wavelength.

For example, one proposed EL device includes an organic EL material portion for emitting light in a blue to blue-green region, an organic EL material portion for emitting light in an ultraviolet region, a fluorescent material portion for emitting red light using the light in the blue to blue-green region emitted from the organic EL material portion as excitation light, a fluorescent material portion for emitting green light using the light in the blue to blue-green region as excitation light, and a fluorescent material portion for emitting blue light using the light in the ultraviolet region as excitation light (see, for example, Patent Literature 1). This EL device can be more easily manufactured than the three-color organic EL device and is economical.

Likewise, a wavelength conversion device that includes a fluorescent layer (wavelength converter) for absorbing excitation light to emit fluorescence and performs wavelength conversion in the fluorescent layer is proposed (see, for example, Patent Literature 2). The wavelength conversion device described in Patent Literature 2 includes a reflective portion on an excitation light incident side of the fluorescent layer. The reflective portion allows excitation light to pass through and reflects fluorescence. The reflective portion of the wavelength conversion device described in Patent Literature 2 reflects isotropically emitted fluorescence and directs the fluorescence to an exit side, thereby efficiently extracting fluorescence.

A color display apparatus that includes a light source for emitting light having an emission peak wavelength in the range of 400 to 500 nm, a liquid crystal display device, and a wavelength converter made of a fluorescent substance is proposed (see, for example, Patent Literature 3 and Non-patent Literature 1). For example, Patent Literature 3 discloses that a RGB fluorescent layer disposed on the outside of a liquid crystal layer can emit light, thereby increasing light-use efficiency and realizing a bright color display apparatus.

### CITATION LIST

### Patent Literature

PTL 1: Japanese Patent No. 2795932
PTL 2: Japanese Unexamined Patent Application Publication No. 2006-276281
PTL 3: Japanese Unexamined Patent Application Publication No. 2000-131683

### Non Patent Literature

NPL 1: IDW '09, p. 1001 (2009)

### SUMMARY OF INVENTION

### Technical Problem

In the structures described in these patent literatures, however, a reflective portion is formed only on the incident side of the fluorescent layer. Thus, fluorescence emitted in a direction other than the excitation light incident side and the fluorescence exit side cannot be effectively utilized. Use of such a wavelength conversion device in a display apparatus causes a problem of high power consumption.

In view of the situations described above, it is an object of the present invention to provide a fluorescent substrate that can improve fluorescence extraction efficiency after wavelength conversion and conversion efficiency (the ratio of extracted fluorescence quantity to excitation light quantity). It is another object of the present invention to provide a display apparatus that includes the fluorescent substrate in combination with an organic EL device and a liquid crystal device. The display apparatus has excellent viewing angle characteristics and can consume less power. It is still another object of the present invention to provide a bright lighting apparatus that can consume less power.

### Solution to Problem

(1) In order to solve the problems described above, a fluorescent substrate according to a first aspect of the present invention includes a substrate, a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, and reflective portions, which face the incident surface and side surfaces of the fluorescent layer in contact with the incident surface. The reflective portions include a first reflective portion that reflects the excitation light and the fluorescence and a second reflective portion disposed on at least part of the incident surface, the second reflective portion allowing at least light having a peak wavelength of the excitation light to pass through and reflecting at least light having a peak wavelength of the fluorescence.

(2) In the fluorescent substrate according to the first aspect of the present invention, the fluorescent layer may include a plurality of fluorescent layers each disposed in a predetermined region on the substrate, a partition surrounding each of the plurality of fluorescent layers may be disposed on a surface of the substrate, and the first reflective portion may be disposed on at least side surface of the partition.

(3) In the fluorescent substrate according to the first aspect of the present invention, the partition may be formed of the material of the first reflective portion.

(4) In the fluorescent substrate according to the first aspect of the present invention, the length from the surface of the substrate to the top of the partition may be larger than the thickness of the fluorescent layer.

(5) In the fluorescent substrate according to the first aspect of the present invention, the first reflective portion may be disposed on a side surface of the fluorescent layer.

(6) In the fluorescent substrate according to the first aspect of the present invention, the second reflective portion may allow 50% or more of the light having a peak wavelength of the excitation light to pass through.

(7) The fluorescent substrate according to the first aspect of the present invention may further include a planarization layer on the incident surface of the fluorescent layer, wherein the second reflective portion is disposed on the planarization layer.

(8) In the fluorescent substrate according to the first aspect of the present invention, the fluorescent layer may contain an inorganic fluorescent substance.

(9) In the fluorescent substrate according to the first aspect of the present invention, the second reflective portion may be a dielectric multilayer film.

(10) In the fluorescent substrate according to the first aspect of the present invention, the second reflective portion may be a thin silver film.

(11) A display apparatus according to a second aspect of the present invention includes a fluorescent substrate and a light source. The fluorescent substrate includes a substrate, a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, and reflective portions, which face the incident surface and side surfaces of the fluorescent layer in contact with the incident surface. The reflective portions include a first reflective portion that reflects the excitation light and the fluorescence and a second reflective portion disposed on at least part of the incident surface, the second reflective portion allowing at least light having a peak wavelength of the excitation light to pass through and reflecting at least light having a peak wavelength of the fluorescence. The light source includes a light-emitting device for emitting ultraviolet light as excitation light with which the fluorescent layer is irradiated.

(12) The display apparatus according to the second aspect of the present invention may further includes a plurality of pixels, including a red color pixel for displaying an object with red light, a green color pixel for displaying an object with green light, and a blue color pixel for displaying an object with blue light, wherein the fluorescent layer may include a red fluorescent layer for emitting red light utilizing the ultraviolet light as the excitation light in the red color pixel, a green fluorescent layer for emitting green light utilizing the ultraviolet light as the excitation light in the green color pixel, and a blue fluorescent layer for emitting blue light utilizing the ultraviolet light as the excitation light in the blue color pixel.

(13) A display apparatus according to a third aspect of the present invention includes a fluorescent substrate and a light source, wherein the fluorescent substrate includes a substrate, a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, and reflective portions, which face the incident surface and side surfaces of the fluorescent layer in contact with the incident surface. The reflective portions include a first reflective portion that reflects the excitation light and the fluorescence and a second reflective portion disposed on at least part of the incident surface, the second reflective portion allowing at least light having a peak wavelength of the excitation light to pass through and reflecting at least light having a peak wavelength of the fluorescence. The light source includes a light-emitting device for emitting blue light as excitation light with which the fluorescent layer is irradiated.

(14) The display apparatus according to the third aspect of the present invention may further includes a plurality of pixels, including a red color pixel for displaying an object with red light, a green color pixel for displaying an object with green light, and a blue color pixel for displaying an object with blue light, wherein the fluorescent layer may include a red fluorescent layer for emitting red light utilizing the blue light as the excitation light in the red color pixel and a green fluorescent layer for emitting green light utilizing the blue light as the excitation light in the green color pixel, and the blue color pixel may include a scattering layer for scattering the blue light.

(15) In display apparatus according to the second or third aspect of the present invention, the light source may be an active-matrix drive light source, which includes a light-emitting device for each of the plurality of pixels and a driver device for driving the light-emitting device.

(16) In the display apparatus according to the second or third aspect of the present invention, light may be extracted from a surface of the substrate opposite the plurality of driver devices.

(17) In the display apparatus according to the second or third aspect of the present invention, the light source may be one of light-emitting diodes, organic electroluminescent devices, and inorganic electroluminescent devices.

(18) In the display apparatus according to the second or third aspect of the present invention, the light source may be a planar light source for emitting light through a light exit surface, and each of the pixels may include a liquid crystal device between the planar light source and the fluorescent substrate, the liquid crystal device controlling the transmittance of light emitted from the planar light source.

(19) A lighting apparatus according to a fourth aspect of the present invention includes a fluorescent substrate and a light source, wherein the fluorescent substrate includes a substrate, a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, and reflective portions, which face the incident surface and side surfaces of the fluorescent layer in contact with the incident surface. The reflective portions include a first reflective portion that reflects the excitation light and the fluorescence and a second reflective portion disposed on at least part of the incident surface, the second reflective portion allowing at least light having a peak wavelength of the excitation light to pass through and reflecting at least light having a peak wavelength of the fluorescence. The light source includes a light-emitting device for emitting excitation light with which the fluorescent layer is irradiated.

### Advantageous Effects of Invention

The present invention can provide a fluorescent substrate that has high light extraction efficiency from a fluorescent substance and high conversion efficiency. The present invention can also provide a display apparatus that includes the fluorescent substrate in combination with an organic EL device and a liquid crystal device. The display apparatus has excellent viewing angle characteristics and can consume less power. The present invention can also provide a bright lighting apparatus that can consume less power.

### BRIEF DESCRIPTION OF DRAWINGS

FIG. 1 is a cross-sectional view of a display apparatus according to a first embodiment of the present invention.

FIG. 2 is a cross-sectional view of a display apparatus according to a modified example of the first embodiment.

FIG. 3 is a cross-sectional view of a display apparatus according to a modified example of the first embodiment.

FIG. 4A is a manufacturing process drawing of a fluorescent substrate according to the first embodiment.

FIG. 4B is a manufacturing process drawing of the fluorescent substrate according to the first embodiment, subsequent to the process illustrated in FIG. 4A.

FIG. 4C is a manufacturing process drawing of the fluorescent substrate according to the first embodiment, subsequent to the process illustrated in FIG. 4B.

FIG. 5 is an explanatory view of an organic EL device for use in a light source of a display apparatus according to the present invention.

FIG. 6A is an explanatory view for a problem of an existing fluorescent substrate.

FIG. 6B is another explanatory view for a problem of an existing fluorescent substrate.

FIG. 6C is a still another explanatory view for a problem of an existing fluorescent substrate.

FIG. 7 is an explanatory view of a LED device for use in a light source of a display apparatus according to the present invention.

FIG. 8 is an explanatory view of an inorganic EL device for use in a light source of a display apparatus according to the present invention.

FIG. 9 is a cross-sectional view of a display apparatus according to a second embodiment of the present invention.

FIG. 10A is a manufacturing process drawing of a fluorescent substrate according to the second embodiment.

FIG. 10B is a manufacturing process drawing of the fluorescent substrate according to the second embodiment, subsequent to the process illustrated in FIG. 10A.

FIG. 10C is a manufacturing process drawing of the fluorescent substrate according to the second embodiment, subsequent to the process illustrated in FIG. 10B.

FIG. 10D is a manufacturing process drawing of the fluorescent substrate according to the second embodiment, subsequent to the process illustrated in FIG. 10C.

FIG. 11 is a plan view of the display apparatus according to the second embodiment.

FIG. 12 is a cross-sectional view of a display apparatus according to a third embodiment of the present invention.

FIG. 13A is a manufacturing process drawing of a fluorescent substrate according to the third embodiment.

FIG. 13B is a manufacturing process drawing of the fluorescent substrate according to the third embodiment, subsequent to the process illustrated in FIG. 13A.

FIG. 13C is a manufacturing process drawing of the fluorescent substrate according to the third embodiment, subsequent to the process illustrated in FIG. 13B.

FIG. 13D is a manufacturing process drawing of the fluorescent substrate according to the third embodiment, subsequent to the process illustrated in FIG. 13C.

FIG. 14 is a cross-sectional view of a display apparatus according to a modified example of the third embodiment according to the present invention.

FIG. 15 is a cross-sectional view of a display apparatus according to a fourth embodiment of the present invention.

FIG. 16A is a schematic view of electronic equipment that includes a display apparatus according to one of the first to fourth embodiments.

FIG. 16B is a schematic view of another electronic equipment that includes a display apparatus according to one of the first to fourth embodiments.

FIG. 17 is a cross-sectional view of a lighting apparatus according to a fifth embodiment of the present invention.

### DESCRIPTION OF EMBODIMENTS

### First Embodiment

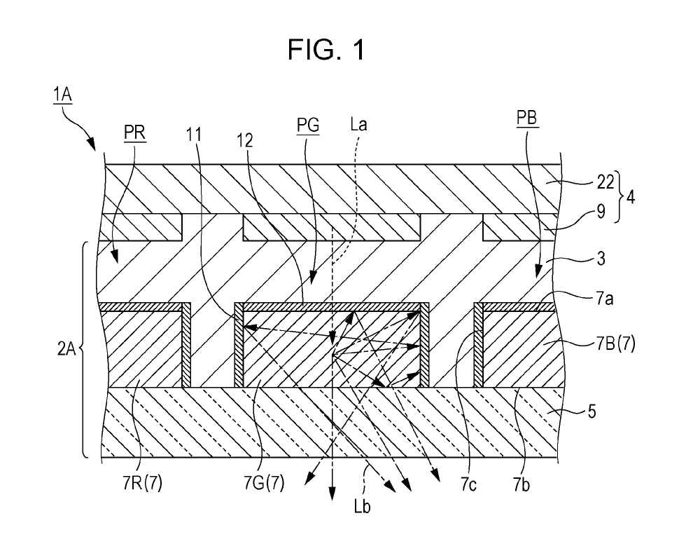

A fluorescent substrate and a display apparatus according to a first embodiment of the present invention will be described below with reference to FIGS. 1 to 8. For the sake of clarity, components in the drawings may have different dimensions and ratios.

FIG. 1 is a general cross-sectional view of a display apparatus 1A according to the first embodiment. The display apparatus 1A includes a fluorescent substrate 2A according to the first embodiment and an organic EL device substrate 4 (a light source). The organic EL device substrate 4 is bonded to the fluorescent substrate 2A with a planarization film 3 interposed therebetween.

In the display apparatus 1A, three display dots of red, green, and blue compose one pixel, which is the smallest unit of an image. The red display dot is hereinafter also referred to as a red color pixel PR, the green display dot is hereinafter also referred to as a green color pixel PG, and the blue display dot is hereinafter also referred to as a blue color pixel PB.

In the display apparatus 1A, ultraviolet light emitted from an organic EL device 9 of the organic EL device substrate 4 serving as a light source enters the fluorescent substrate 2A as excitation light La. In the fluorescent substrate 2, a fluorescent substance of the fluorescent substrate 2A is excited by the incident excitation light La to emit fluorescence Lb. More specifically, the red color pixel PR emits red fluorescence, the green color pixel PG emits green fluorescence, and the blue color pixel PB emits blue fluorescence. These colored lights produce full-color display.

These components will be described in detail below.

### (Fluorescent Substrate)

The fluorescent substrate 2A includes fluorescent layers 7 on a top surface of a substrate main body 5 and the planarization film 3 covering the fluorescent layers 7. The fluorescent layers 7 include a plurality of fluorescent layers 7R corresponding to respective red color pixels PRs, a plurality of fluorescent layers 7G corresponding to respective green color pixels PGs, and a plurality of fluorescent layers 7B corresponding to respective red color pixels PBs. The plurality of fluorescent layers 7R, 7G, and 7B are composed of different fluorescent materials in order to emit fluorescence Lb having different colors from different pixels. The planarization of the fluorescent layers 7R, 7G, and 7B with the planarization film 3 can prevent depletion between the organic EL device 9 described below and the fluorescent layers 7R, 7G, and 7B and improve adhesion between the organic EL device substrate 4 and the fluorescent substrate 2A.

The excitation light La enters the plurality of fluorescent layers 7 through the incident surface 7a facing the organic EL device substrate 4, and the fluorescence Lb generated in the fluorescent layers 7 is emitted through an exit surface 7b of the substrate main body 5. Each of the fluorescent layers 7 includes a first reflective portion (reflective portion) 11 on its side surfaces 7c. The first reflective portions (reflective portions) 11 reflect the excitation light La and the fluorescence Lb. Each of the fluorescent layers 7 includes a second reflective portion (reflective portion) 12 on its incident surface 7a. The second reflective portion (reflective portion) 12 allows the excitation light La to pass through and reflects the fluorescence Lb.

The substrate main body 5 needs to allow light in an emission wavelength range of the fluorescent substance to pass through in order to extract light from the fluorescent layers 7R, 7G, and 7B. Thus, examples of the material of the substrate main body 5 include inorganic material substrates made of glass or quartz and plastic substrates made of poly(ethylene terephthalate), polycarbazole, or polyimide. The first embodiment is not limited to these substrates. Plastic substrates are preferred because they can be curved or bent without causing stress.

More preferably, plastic substrates are coated with an inorganic material in order to improve gas barrier properties. This can prevent the deterioration of an organic EL device due to moisture permeation, which is the biggest problem of a plastic substrate used as an organic EL device substrate. It is known that organic EL devices deteriorate even with a small amount of moisture.

The fluorescent layers 7R, 7G, and 7B are composed of a red fluorescent layer 7R, a green fluorescent layer 7G, and a blue fluorescent layer 7B that absorb excitation light emitted from the organic EL device 9 that emits the excitation light La and emit red light, green light, and blue light, respectively. If necessary, a fluorescent layer that emits cyan light or yellow light may be added to the pixels. In this case, the color purity of a pixel that emits cyan light or yellow light is set in the outside of a triangle of the color purities of the pixels that emit red light, green light, and blue light on a chromaticity diagram. This can improve the color reproducibility of a display apparatus including pixels that emit light of three primary colors red, green, and blue.

The fluorescent layers 7R, 7G, and 7B may be composed of the following fluorescent materials alone or may contain an additive agent. These fluorescent materials may be dispersed in a high-molecular material (binding resin) or an inorganic material. The fluorescent materials in the first embodiment may be known fluorescent materials. These fluorescent materials are divided into organic fluorescent materials and inorganic fluorescent materials. Although specific compounds of these fluorescent materials are described below, the first embodiment is not limited to these materials.

Among organic fluorescent materials, examples of fluorescent dyes that convert ultraviolet excitation light into blue light include stilbenzene dyes, such as 1,4-bis(2-methylstyryl)benzene and trans-4,4′-diphenylstilbenzene, and coumarin dyes, such as 7-hydroxy-4-methylcoumarin.

Examples of fluorescent dyes that convert ultraviolet and blue excitation light into green light include coumarin dyes, such as 2,3,5,6-1H,4H-tetrahydro-8-triflomethylquinolizine(9,9a,1-gh)coumarin (coumarin 153), 3-(2′-benzothiazolyl)-7-diethylaminocoumarin (coumarin 6), and 3-(2′-benzimidazolyl)-7-N,N-diethylaminocoumarin (coumarin 7), and naphthalimide dyes, such as Basic Yellow 51, Solvent Yellow 11, and Solvent Yellow 116.

Examples of fluorescent dyes that convert ultraviolet and blue excitation light into red light include cyanine dyes, such as 4-dicyanomethylene-2-methyl-6-(p-dimethylaminostylryl)-4H-pyran, pyridine dyes, such as 1-ethyl-2-[4-(p-dimethylaminophenyl)-1,3-butadienyl]-pyridinium-perchlorate, and rhodamine dyes, such as rhodamine B, rhodamine 6G, rhodamine 3B, rhodamine 101, rhodamine 110, Basic Violet 11, and sulforhodamine 101.

Among inorganic fluorescent materials, examples of fluorescent substances that convert ultraviolet excitation light into blue light include Sr₂P₂O₇:Sn⁴⁺, Sr₄Al₁₄O₂₅:Eu²⁺, BaMgAl₁₀O₁₇:Eu²⁺, SrGa₂S₄:Ce³⁺, CaGa₂S₄:Ce³⁺, (Ba, Sr)(Mg, Mn)Al₁₀O₁₇:Eu²⁺, (Sr, Ca, Ba₂, 0Mg)₁₀(PO₄)₆Cl₂:Eu²⁺, BaAl₂SiO₈:Eu²⁺, Sr₂P₂O₇:Eu²⁺, Sr₅ (PO₄)₃Cl:Eu²⁺, (Sr, Ca, Ba)₅(PO₄)₃Cl:Eu²⁺, BaMg₂Al₁₆O₂₇:Eu²⁺, (Ba, Ca)₅(PO₄)₃Cl:Eu²⁺, Ba₃MgSi₂O₈:Eu²⁺, and Sr₃MgSi₂O₈:Eu²⁺.

Examples of fluorescent substances that convert ultraviolet and blue excitation light into green light include (BaMg)Al₁₆O₂₇:Eu²⁺,Mn²⁺, Sr₄Al₁₄O₂₅:Eu²⁺, (SrBa)Al₁₂Si₂O₈:Eu²⁺, (BaMg)₂SiO₄:Eu²⁺, Y₂SiO₅:Ce³⁺,Tb³⁺, Sr₂P₂O₇—Sr₂B₂O₅:Eu²⁺, (BaCaMg)₅(PO₄)₃Cl:Eu²⁺, Sr₂Si₃O₈-2SrCl₂:Eu²⁺, Zr₂SiO₄, MgAl₁₁O₁₉:Ce³⁺,Tb³⁺, Ba₂SiO₄:Eu²⁺, Sr₂SiO₄:Eu²⁺, and (BaSr)SiO₄:Eu²⁺.

Examples of fluorescent substances that convert ultraviolet and blue excitation light into red light include Y₂O₂S:Eu³⁺, YAlO₃:Eu³⁺, Ca₂Y₂(SiO₄)₆:Eu³⁺, LiY₉(SiO₄)₆O₂:Eu³⁺, YVO₄:Eu³⁺, CaS:Eu³⁺, Gd₂O₃:Eu³⁺, Gd₂O₂S:Eu³⁺, Y(P,V) O₄:Eu³⁺, Mg₄GeO_{5.5}F:Mn⁴⁺, Mg₄GeO₆:Mn⁴⁺, K₅Eu_{2.5}(WO₄)_{6.25}, Na₅Eu_{2.5}(WO₄)_{6.25}, K₅Eu_{2.5}(MoO₄)_{6.25}, and Na₅Eu_{2.5}(MoO₄)_{6.25}.

The inorganic fluorescent substances may be subjected to surface modification, if necessary. A method for surface modification may be chemical treatment with a silane coupling agent, physical treatment by the addition of submicron fine particles, or a combination thereof.

In view of stability, such as degradation by excitation light or degradation by light emission, use of inorganic materials is preferred.

The inorganic fluorescent substances preferably have an average particle size (d₅₀) in the range of 0.5 to 50 μm. An average particle size of 1 μm or less results in markedly low luminous efficiency of the fluorescent substances. At an average particle size of 50 μm or more, it is very difficult to form flat fluorescent layers 7R, 7G, and 7B. In this case, for example, depletion (an air layer) having a refractive index of 1.0 is formed between a fluorescent layer having a refractive index of approximately 2.3 and an organic EL device having a refractive index of approximately 1.7. This causes a problem that light from the organic EL device 9 does not efficiently reach the fluorescent layers 7R, 7G, and 7B, resulting in a decrease in luminous efficiency of the fluorescent layers 7R, 7G, and 7B. Furthermore, since the fluorescent layers 7R, 7G, and 7B are difficult to make flat, when combined with a liquid crystal device as described below in a fourth embodiment, this results in variations in the distance between electrodes disposed on the top and bottom surfaces of a liquid crystal layer, an uneven electric field, and unsteady operation of the liquid crystal layer.

The fluorescent layers 7R, 7G, and 7B may be formed by a known wet process, for example, a coating method, such as a spin coating method, a dipping method, a doctor blade method, a discharge coating method, or a spray coating method, or a printing method, such as an ink jet method, a letterpress printing method, an intaglio printing method, a screen printing method, or a microgravure coating method, using fluorescent layer forming coating liquids containing the fluorescent materials and resin materials dissolved or dispersed in solvents, or a known dry process, such as a resistance-heating evaporation method, an electron beam (EB) evaporation method, a molecular beam epitaxy (MBE) method, a sputtering method, or an organic vapor phase deposition (OVPD) method, or a laser transfer method of the materials described above.

Using photosensitive resins as the resin materials, the fluorescent layers 7R, 7G, and 7B can be patterned by a photolithography method. Examples of the photosensitive resins include photosensitive resins having a reactive vinyl group (photo-curing resist materials), such as acrylic acid resins, methacrylic acid resins, poly(vinyl cinnamate) resins, and hard rubber resins. These photosensitive resins may be used alone or in combination. The fluorescent materials may be directly patterned by a wet process, such as the ink jet method, the letterpress printing method, the intaglio printing method, or the screen printing method, a known dry process, such as the resistance-heating evaporation method using a shadow mask, the electron beam (EB) evaporation method, the molecular beam epitaxy (MBE) method, the sputtering method, or the organic vapor phase deposition (OVPD) method, or the laser transfer method.

The fluorescent layers 7R, 7G, and 7B preferably have a thickness in the range of approximately 100 nm to 100 μm, more preferably approximately 1 to 100 μm. The first embodiment describes the emission of ultraviolet light from the organic EL device 9. In the case that blue light is emitted from the organic EL device 9, however, blue light cannot be sufficiently absorbed at a thickness of less than 100 nm, thus causing problems of a decrease in luminous efficiency and a decrease in color purity due to contamination of desired colored light with blue transmitting light. Thus, in order to increase the absorption of light from the organic EL device 9 and reduce blue transmitting light to the extent that the blue transmitting light has negligible adverse effects on color purity, the thickness is preferably 1 μm or more.

A thickness of more than 100 μm does not necessarily result in an increase in efficiency because excitation light La from the organic EL device 9 can be sufficiently absorbed even at a smaller thickness. Thus, this only results in a waste of material and an increase in material cost.

When blue light is emitted from the organic EL device 9, the fluorescent layer 7B in FIG. 1 may be substituted by a light scattering layer containing light scattering particles, and thereby the blue light emitted from the organic EL device 9 may be directly used for display.

The light scattering particles may be made of an organic material or an inorganic material. In consideration of lightfastness, however, an inorganic material is preferred.

This can more isotropically and effectively diffuse or scatter directional light from the organic EL device. Use of an inorganic material can provide a light scattering layer that is resistant to light and heat.

Such light scattering particles preferably have high transparency. For example, light scattering particles made of an inorganic material may be particles (fine particles) mainly composed of an oxide of at least one metal selected from the group consisting of silicon, titanium, zirconium, aluminum, indium, zinc, tin, and antimony. Examples of such particles include silica beads (refractive index: 1.44), alumina beads (refractive index: 1.63), titanium oxide beads (refractive index: 2.50 (anatase), 2.70 (rutile)), oxidized zirconia beads (refractive index: 2.05), and zinc oxide beads (refractive index: 2.00).

Examples of particles made of an organic material (organic fine particles) for use as light scattering particles include poly(methyl methacrylate) beads (refractive index: 1.49), acryl beads (refractive index: 1.50), acryl-styrene copolymer beads (refractive index: 1.54), melamine beads (refractive index: 1.57), high refractive index melamine beads (refractive index: 1.65), polycarbonate beads (refractive index: 1.57), styrene beads (refractive index: 1.60), cross-linked polystyrene beads (refractive index: 1.61), poly(vinyl chloride) beads (refractive index: 1.60), benzoguanamine-melamine formaldehyde beads (refractive index: 1.68), and silicone beads (refractive index: 1.50).

The resin materials used in combination with the light scattering particles are preferably transparent or translucent resins. Examples of the resin materials include melamine resins (refractive index: 1.57), nylon (refractive index: 1.53), polystyrene (refractive index: 1.60), melamine beads (refractive index: 1.57), polycarbonate (refractive index: 1.57), poly(vinyl chloride) (refractive index: 1.60), poly(vinylidene chloride) (refractive index: 1.61), poly(vinyl acetate) (refractive index: 1.46), polyethylene (refractive index: 1.53), poly(methyl methacrylate) (refractive index: 1.49), polyMBS (refractive index: 1.54), intermediate-density polyethylene (refractive index: 1.53), high-density polyethylene (refractive index: 1.54), tetrafluoroethylene (refractive index: 1.35), polychlorotrifluoroethylene (refractive index: 1.42), and polytetrafluoroethylene (refractive index: 1.35).

The first reflective portions 11 may be formed of a reflective metal, such as aluminum, silver, gold, an aluminum-lithium alloy, an aluminum-neodymium alloy, or an aluminum-silicon alloy. Aluminum or silver is preferred because they have high reflectance in the entire visible light region. These materials are only examples, and the first embodiment is not limited to these materials.

The first reflective portions 11 may be formed by screen printing, a resistance-heating evaporation method, an electron beam (EB) evaporation method, a molecular beam epitaxy (MBE) method, or a sputtering method.

The first reflective portions 11 may be formed by another method.

The second reflective portion 12 disposed on the incident surface 7a of each of the fluorescent layers 7 allows the excitation light La to pass through and reflects the fluorescence Lb from the fluorescent layers 7. The transmittance of the excitation light La passing through the second reflective portion 12 is preferably 50% or more at a peak wavelength of the excitation light La. When the transmittance of the excitation light at a peak wavelength of the excitation light La is less than 50%, the efficiency of extracting the fluorescence Lb emitted from the fluorescent layers 7 from the exit surface 7b is the same whether the second reflective portion 12 is formed or not. Thus, there is no effect of the second reflective portion 12.

More suitably, the transmittance of the excitation light passing through the second reflective portion 12 is 60% or more at a peak wavelength of the excitation light La, and the second reflective portion 12 preferably has a reflectance of 60% or more at a peak wavelength of the fluorescence Lb emitted from the fluorescent layers 7. Thus, a component of the fluorescence Lb emitted from the fluorescent layers 7 toward the incident surface 7a can be efficiently extracted through the exit surface 7b.

More specifically, the second reflective portion 12 may be, but is not limited to, a thin metal film, a dielectric multilayer film, a thin metal film glass, an inorganic material substrate, for example, made of quartz, or a plastic substrate, for example, made of poly(ethylene terephthalate), polycarbazole, or polyimide.

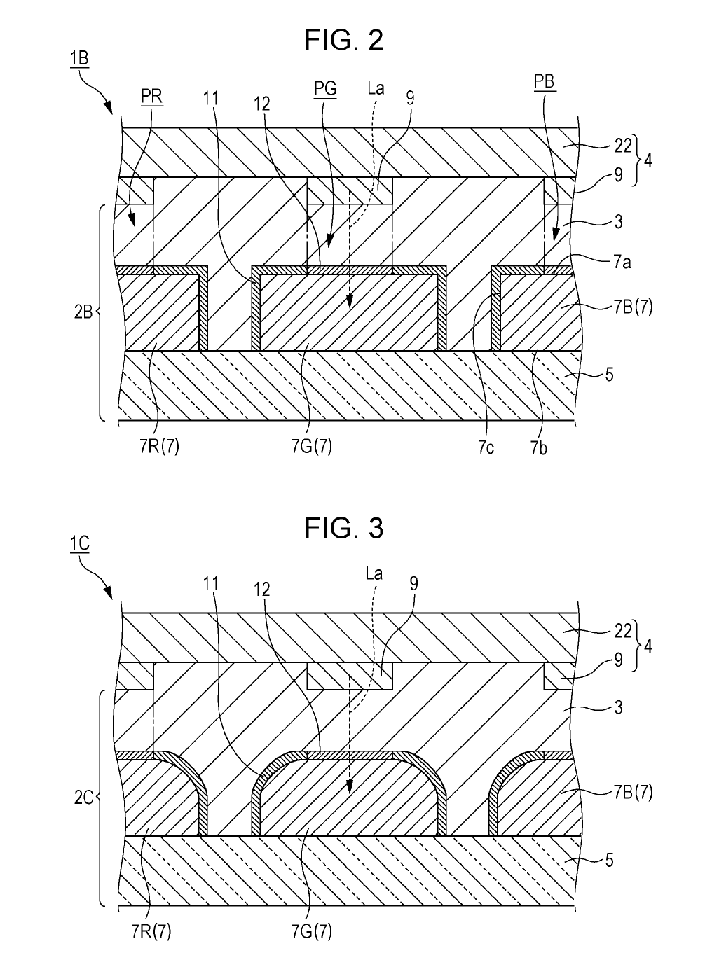

The second reflective portion 12 does not necessarily cover the entire surface of the incident surface 7a, provided that the second reflective portion 12 is disposed at the incident position of the excitation light La. For example, as in a fluorescent substrate 1B of a display apparatus 1B according to a modified example illustrated in FIG. 2, a first reflective portion 11 may partly cover an incident surface 7a of fluorescent layers 7 from an end toward the center of the incident surface 7a, and the remainder of the incident surface 7a may be covered with a second reflective portion 12.

In such a case, when the top view area of an organic EL device 9 that emits excitation light La toward the fluorescent layers 7 is the same as the top view area of the first reflective portion 11, and the first reflective portion 11 is disposed on the optical path of the excitation light La, the excitation light La can efficiently enter the fluorescent layers 7.

Although the cross-sectional shape of the fluorescent layers 7 in FIGS. 1 and 2 is rectangular, it is not limited to rectangular. For example, as in a fluorescent substrate 2C of a display apparatus 1C according to a modified example illustrated in FIG. 3, the cross-sectional shape of fluorescent layers 7 may have round corners rather than the shape of a rectangle. The cross-sectional shape of the fluorescent layers 7 may also be semicircular or arcuate.

In the fluorescent layers 7 having such a shape, a portion of the surface of each of the fluorescent layers 7 facing the organic EL device 9 serves as an incident surface of excitation light, and the second reflective portion 12 may be disposed on the incident surface.

In the fluorescent substrates 2A, 2B, and 2C illustrated in FIGS. 1, 2, and 3, the second reflective portion 12 is selectively disposed on the surface of each of the fluorescent layers 7. The second reflective portion 12, however, is not selectively disposed on the surface of each of the fluorescent layers 7, and may be disposed over the entire surface of the substrate main body 5 and cover the first reflective portions 11.

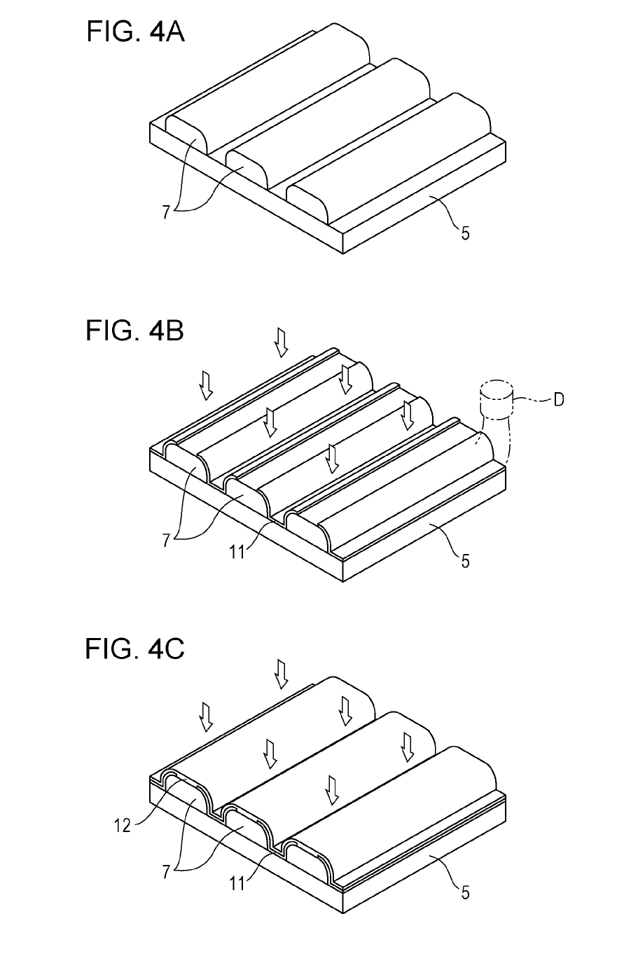

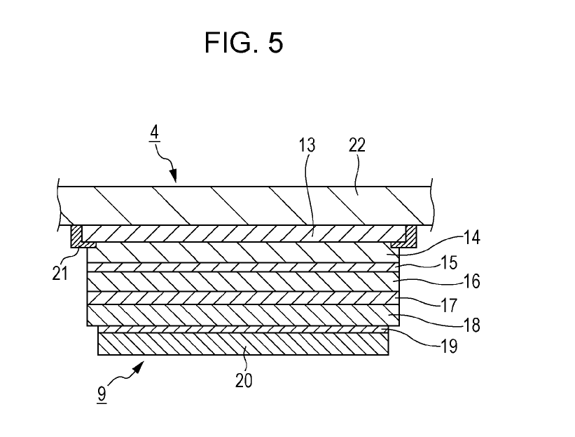

FIGS. 4A to 4C are process drawings of one example of a method for manufacturing a fluorescent substrate. A method for manufacturing the fluorescent substrate 2C illustrated in FIG. 3 will be described below as an example.

First, as illustrated in FIG. 4A, a fluorescent layer forming coating liquid containing a fluorescent material and a resin material dissolved or dispersed in a solvent is applied to a substrate main body 5 by a screen printing method and is dried to form a plurality of fluorescent layers 7 each patterned in the shape of a belt. A plurality of fluorescent layers of different types may be formed by performing the screen printing and drying processes more than once to form the fluorescent layers 7.

As illustrated in FIG. 4B, a silver paste is then applied to a region of the substrate main body 5 on which no fluorescent layer 7 is formed and to edges of the fluorescent layers 7 by a dispenser method. In FIG. 4B, the application of the silver paste with a dispenser D is indicated by a broken line. The entire substrate coated with the silver paste is baked at 300° C. to form first reflective portions 11 such that the fluorescent layers 7 are partly exposed.

As illustrated in FIG. 4C, a silver film, for example, having a thickness of 25 nm is then formed on the fluorescent layers 7 and the first reflective portions 11 over the entire surface of the substrate main body 5 by a sputtering method to form a second reflective portion 12. The second reflective portion 12 is formed over the entire surface of the fluorescent layers 7 and the first reflective portions 11. The surfaces of the fluorescent layers 7 exposed between the first reflective portions 11 are covered with the second reflective portion 12, thus completing the fluorescent substrate 2C.

Since thin silver films allow ultraviolet light to sufficiently pass through, ultraviolet light can be used as excitation light in the fluorescent substrate 2C including the second reflective portion 12, which is a thin silver film. Thus, the second reflective portion 12 can be formed using one type of material. This can simplify the manufacturing process of the fluorescent substrate 2C.

### (Organic EL Device Substrate)

The organic EL device substrate 4 of the display apparatus 1A according to the first embodiment, which functions as a light source, will be described below. FIG. 5 is a cross-sectional view of a principal part of the organic EL device substrate 4.

The organic EL device substrate 4 includes a plurality of organic EL devices 9. Each of the organic EL devices 9 includes an anode 13, a hole-injection layer 14, a hole-transport layer 15, a light-emitting layer 16, a hole-blocking layer 17, an electron-transport layer 18, an electron-injection layer 19, and a cathode 20 on a substrate main body 22. An end face of the anode 13 is covered with an edge cover 21.

The organic EL device substrate 4 emits ultraviolet light, which desirably has an emission peak in the range of 360 to 410 nm. The structure of the organic EL device substrate 4 is not limited to that described above. The organic EL device substrate 4 may be a known substrate, provided that the organic EL device substrate 4 includes an organic EL layer made of at least an organic light-emitting material between the anode 13 and the cathode 20. The layers from the hole-injection layer 14 to the electron-injection layer 19 are hereinafter also referred to as an organic EL layer.

The plurality of organic EL devices 9 constitute a matrix of red color pixels PR, green color pixels PG, and blue color pixels PB and are independently on-off controlled. A method for driving the plurality of organic EL devices 9 may be active-matrix drive or passive-matrix drive. An example using an active-matrix organic EL device substrate will be described in detail below in a third embodiment.

The components of the organic EL device substrate will be described in detail below.

The substrate main body 22 may be made of substantially the same material as the substrate main body 5 of the fluorescent substrate 2A. Examples of the material of the substrate main body 22 include insulating substrates, such as inorganic material substrates made of glass or quartz, plastic substrates made of poly(ethylene terephthalate), polycarbazole, or polyimide, and ceramic substrates made of alumina, metal substrates made of aluminum (Al) or iron (Fe), substrates coated with an insulator, such as silicon oxide (SiO₂) or an organic insulating material, and metal substrates made of Al that have been subjected to insulation treatment, such as anodic oxidation. The first embodiment is not limited to these substrates.

Plastic substrates and metal substrates are preferred because they can be curved or bent without causing stress. Plastic substrates coated with an inorganic material and metal substrates coated with an inorganic insulating material are more preferred. This can prevent the deterioration of an organic EL due to moisture permeation, which is the biggest problem of a plastic substrate used as an organic EL substrate. This can also prevent a leakage (a short circuit) due to a projection of a metal substrate, which is the biggest problem of a metal substrate used as an organic EL substrate. An organic EL layer generally has a very small thickness in the range of approximately 100 to 200 nm, and it is known that a projection often causes a leakage current or a short circuit in a pixel unit.

When light from an organic EL layer is extracted from a side opposite a substrate, there is no restrictions on the substrate main body 22. When light from an organic EL layer is extracted from a substrate, the substrate main body 22 must be transparent or translucent.

The electrode materials of the anode 13 and the cathode 20 may be known electrode materials. In order to efficiently inject positive holes into the light-emitting layer 16, the transparent electrode material of the anode 13 may be a metal, such as gold (Au), platinum (Pt), or nickel (Ni), or an oxide of indium (In) and tin (Sn) (ITO), an oxide of tin (Sn) (SnO₂), or an oxide of indium (In) and zinc (Zn) (IZO (registered trademark)), having a work function of 4.5 eV or more. In order to efficiently inject electrons into the light-emitting layer 16, the material of the cathode 20 may be a metal, such as lithium (Li), calcium (Ca), cerium (Ce), barium (Ba), or aluminum (Al), or an alloy containing the metal, such as a Mg:Ag alloy or a Li:Al alloy, having a work function of 4.5 eV or less.

The anode 13 and the cathode 20 may be formed by a known method, such as an EB evaporation method, a sputtering method, an ion plating method, or a resistance-heating evaporation method, using the material described above. The first embodiment is not limited to these forming methods. If necessary, an electrode thus formed may be patterned by a photolithography method or a laser abrasion method, or a directly patterned electrode may be formed by a photolithography method or a laser abrasion method in combination with a shadow mask. The anode 13 and the cathode 20 preferably have a thickness of 50 nm or more. A thickness of less than 50 nm may result in a high wire resistance and a high driving voltage.

When the microcavity effect is utilized to improve color purity, luminous efficiency, or front luminance, the anode 13 (cathode 20) is preferably a translucent electrode so as to extract light emitted from the light-emitting layer 16 from the anode 13 (cathode 20). The material may be a translucent metal electrode material alone or a combination of a translucent metal electrode material and a transparent electrode material. The translucent electrode material is preferably silver in terms of reflectance and transmittance. The translucent electrode preferably has a thickness in the range of 5 to 30 nm. A thickness of less than 5 nm results in insufficient light reflection and an insufficient interferential effect. A thickness of more than 30 nm may result in a marked decrease in transmittance and a decrease in luminance or efficiency. An electrode opposite the light extraction side is preferably an electrode having a high optical reflectance.

In this case, the electrode material may be a reflective metal electrode, such as aluminum, silver, gold, an aluminum-lithium alloy, an aluminum-neodymium alloy, or an aluminum-silicon alloy, or an electrode of a combination of a transparent electrode and a reflective metal electrode (reflective electrode).

The organic EL layer in the first embodiment may have a monolayer structure of an organic light-emitting layer or a multilayer structure of an organic light-emitting layer, a charge-transport layer, and a charge-injection layer, more specifically the following structure. The first embodiment is not limited to these structures.

(1) Organic light-emitting layer,

(2) hole-transport layer/organic light-emitting layer,

(3) organic light-emitting layer/electron-transport layer,

(4) hole-transport layer/organic light-emitting layer/electron-transport layer,

(5) hole-injection layer/hole-transport layer/organic light-emitting layer/electron-transport layer,

(6) hole-injection layer/hole-transport layer/organic light-emitting layer/electron-transport layer/electron-injection layer,

(7) hole-injection layer/hole-transport layer/organic light-emitting layer/hole-blocking layer/electron-transport layer,

(8) hole-injection layer/hole-transport layer/organic light-emitting layer/hole-blocking layer/electron-transport layer/electron-injection layer,

(9) hole-injection layer/hole-transport layer/electron-blocking layer/organic light-emitting layer/hole-blocking layer/electron-transport layer/electron-injection layer.

The first embodiment has the structure (8), as illustrated in FIG. 5.

The light-emitting layer, the hole-injection layer, the hole-transport layer, the hole-blocking layer, the electron-blocking layer, the electron-transport layer, and the electron-injection layer in the structures described above may have a monolayer structure or a multilayer structure. The organic light-emitting layer may be made of the following organic light-emitting material alone or a combination of a luminous dopant and a host material. The organic light-emitting layer may contain a hole-transport material, an electron-transport material, and/or an additive agent (such as a donor or an acceptor). These materials may be dispersed in a high-molecular material (binding resin) or an inorganic material. In terms of luminous efficiency and life, a luminous dopant dispersed in a host material is preferred.

The organic light-emitting material may be a known light-emitting material for use in organic ELs. Such light-emitting materials are divided into low-molecular light-emitting materials, high-molecular light-emitting materials, and the like. Although specific compounds of these light-emitting materials are described below, the first embodiment is not limited to these materials. The light-emitting materials may be divided into fluorescent materials, phosphorescent materials, and the like. In terms of lower power consumption, phosphorescent materials having high luminous efficiency are preferably used.

A luminous dopant optionally contained in the light-emitting layer may be a known dopant material for use in organic ELs. Such a dopant material, for example, an ultraviolet-emitting material may be a fluorescent material, such as p-quaterphenyl, 3,5,3,5tetra-t-butylsexiphenyl, or 3,5,3,5tetra-t-butyl-p-quinquephenyl. A blue-light-emitting material may be a fluorescent material, such as a styryl derivative, or a phosphorescent organometallic complex, such as bis[(4,6-difluorophenyl)-pyridinato-N,C2′]picolinate iridium (III) (Flrpic) or bis(4′,6′-difluorophenylporidinato)tetrakis(1-Pyrazoyl)borate iridium (III) (FIr₆).

The host material for the dopant may be a known host material for use in organic ELs. Examples of such a host material include the low-molecular light-emitting materials and the high-molecular light-emitting materials described above, carbazole derivatives, such as 4,4′-bis(carbazole)biphenyl, 9,9-di(4-dicarbazole-benzyl)fluorene (CPF), 3,6-bis(triphenylsilyl)carbazole (mCP), and (PCF), aniline derivatives, such as 4-(diphenylphosphoyl)-N,N-diphenylaniline (HM-A1), and fluorene derivatives, such as 1,3-bis(9-phenyl-9H-fluoren-9-yl)benzene (mDPFB) and 1,4-bis(9-phenyl-9H-fluoren-9-yl)benzene (pDPFB).

Charge injection and transport layers are divided into charge-injection layers (a hole-injection layer and an electron-injection layer) and charge-transport layers (a hole-transport layer and an electron-transport layer) in order to efficiently perform injection of electric charges (positive holes and electrons) from an electrode and transport (injection) into a light-emitting layer. The charge injection and transport layers may be made of the following charge injection and transport material alone or may contain an additive agent (such as a donor or an acceptor). These materials may be dispersed in a high-molecular material (binding resin) or an inorganic material.

The charge injection and transport material may be a known charge transport material for use in organic ELs and organic photoconductors. Such charge injection and transport materials are divided into hole injection and transport materials and electron injection and transport materials. Although specific compounds of these charge injection and transport materials are described below, the first embodiment is not limited to these materials.

Examples of the hole-injection and hole-transport materials include oxides, such as vanadium oxide (V₂O₅) and molybdenum oxide (MoO₂), inorganic p-type semiconductor materials, aromatic tertiary amine compounds, such as porphyrin compounds, N,N′-bis(3-methylphenyl)-N,N′-bis(phenyl)-benzidine (TPD), and N,N′-di(naphthalen-1-yl)-N,N′-diphenyl-benzidine (NPD), low-molecular-weight materials, such as hydrazone compounds, quinacridone compounds, and styrylamine compounds, and high-molecular materials, such as polyaniline (PANI), polyaniline-camphorsulfonic acid (PANI-CSA), 3,4-polyethylenedioxythiophene/polystyrenesulfonate (PEDOT/PSS), poly(triphenylamine) derivatives (Poly-TPD), polyvinylcarbazole (PVCz), poly(p-phenylenevinylene) (PPV), and poly(p-naphthalenevinylene) (PNV).

In order to efficiently perform the injection and transport of positive holes from an anode, a material for the hole-injection layer preferably has a lower energy level of the highest occupied molecular orbital (HOMO) than hole injection and transport materials for use in the hole-transport layer. A material for the hole-transport layer preferably has higher hole mobility than hole injection and transport materials for use in the hole-injection layer.

In order to improve the injection and transport of positive holes, the hole injection and transport materials are preferably doped with an acceptor. The acceptor may be a known acceptor material for use in organic ELs. Although specific compounds of the acceptor are described below, the first embodiment is not limited to these materials.

Examples of the acceptor material include inorganic materials, such as Au, Pt, W, Ir, POCl₃, AsF₆, Cl, Br, I, vanadium oxide (V₂O₅), and molybdenum oxide (MoO₂), compounds having a cyano group, such as 7,7,8,8,-tetracyanoquinodimethane (TCNQ), tetrafluorotetracyanoquinodimethane (TCNQF₄), tetracyanoethylene (TCNE), hexacyanobutadiene (HCNB), and dicyclodicyanobenzoquinone (DDQ), compounds having a nitro group, such as trinitrofluorenone (TNF) and dinitrofluorenone (DNF), and organic materials, such as fluoranil, chloranil, and bromanil. Among these, the compounds having a cyano group, such as TCNQ, TCNQF₄, TCNE, HCNB, and DDQ, are more preferred because these compounds can effectively increase the carrier concentration.

Examples of electron-injection and electron-transport materials include low-molecular-weight materials, such as inorganic materials of n-type semiconductor, oxadiazole derivatives, triazole derivatives, thiopyrazine dioxide derivatives, benzoquinone derivatives, naphthoquinone derivatives, anthraquinone derivatives, diphenoquinone derivatives, fluorenone derivatives, and benzodifuran derivatives, and high-molecular materials, such as poly(oxadiazole) (Poly-OXZ) and polystyrene derivatives (PSS). In particular, the electron-injection materials include fluorides, such as lithium fluoride (LiF) and barium fluoride (BaF₂), and oxides, such as lithium oxide (Li₂O).

In order to efficiently perform the injection and transport of electrons from a cathode, a material for the electron-injection layer preferably has a higher energy level of the lowest unoccupied molecular orbital (LUMO) than electron injection and transport materials for use in the electron-transport layer. A material for the electron-transport layer preferably has higher electron mobility than electron injection and transport materials for use in the electron-injection layer.

In order to improve the injection and transport of electrons, the electron injection and transport materials are preferably doped with a donor. The donor may be a known donor material for use in organic ELs. Although specific compounds of the donor are described below, the first embodiment is not limited to these materials.

Examples of the donor material include inorganic materials, such as alkali metals, alkaline-earth metals, rare-earth elements, Al, Ag, Cu, and In, and organic materials, for example, anilines, phenylenediamines, benzidines (such as N,N,N′,N′-tetraphenylbenzidine, N,N′-bis-(3-methylphenyl)-N,N′-bis-(phenyl)-benzidine, and N,N′-di(naphthalene-1-yl)-N,N′-diphenyl-benzidine), compounds having an aromatic tertiary amine skeleton, such as triphenylamines (such as triphenylamine, 4,4′,4″-tris(N,N-diphenyl-amino)-triphenylamine, 4,4′,4″-tris(N-3-methylphenyl-N-phenyl-amino)-triphenylamine, and 4,4′,4″-tris(N-(1-naphthyl)-N-phenyl-amino)-triphenylamine) and triphenyldiamines (N,N′-di-(4-methyl-phenyl)-N,N′-diphenyl-1,4-phenylenediamine), condensed polycyclic compounds (the condensed polycyclic compounds may have a substituent), such as phenanthrene, pyrene, perylene, anthracene, tetracene, and pentacene, tetrathiafulvalenes (TTFs), dibenzofuran, phenothiazine, and carbazole.

Among these, compounds having an aromatic tertiary amine skeleton, condensed polycyclic compounds, and alkali metals are more preferred because these compounds can effectively increase the carrier concentration.

The organic EL layers, including the light-emitting layer, the hole-transport layer, the electron-transport layer, the hole-injection layer, and the electron-injection layer, may be formed by a known wet process, for example, a coating method, such as a spin coating method, a dipping method, a doctor blade method, a discharge coating method, or a spray coating method, or a printing method, such as an ink jet method, a letterpress printing method, an intaglio printing method, a screen printing method, or a microgravure coating method, using coating liquids for forming the organic EL layers containing the materials described above dissolved or dispersed in solvents, or a known dry process, such as a resistance-heating evaporation method, an electron beam (EB) evaporation method, a molecular beam epitaxy (MBE) method, a sputtering method, or an organic vapor phase deposition (OVPD) method, or a laser transfer method using the materials described above. When the organic EL layers are formed by a wet process, the coating liquids for forming the organic EL layers may contain an additive agent for controlling the physical properties of the coating liquids, such as a leveling agent and/or a viscosity modifier.

Each of the organic EL layers preferably has a thickness in the range of approximately 1 to 1000 nm, more preferably 10 to 200 nm. A thickness of less than 10 nm results in lack of essentially required physical properties (such as electric charge injection characteristics, transport characteristics, and containment characteristics). Furthermore, foreign matter, such as dust, may cause pixel defects. A thickness of more than 200 nm results in increases in driving voltage and power consumption due to a resistance component of the organic EL layers.

In accordance with the first embodiment, an edge cover 21 is formed at an end of the anode 13 so as to prevent a leakage current from occurring between the anode 13 and the cathode 20. The edge cover 21 may be formed by a known method, such as an EB evaporation method, a sputtering method, an ion plating method, or a resistance-heating evaporation method, using an insulating material. The edge cover 21 may be patterned by a known dry or wet photolithography method. The first embodiment is not limited to these forming method. The material of the edge cover 21 may be a known insulating material, although the first embodiment is not particularly limited to the material. The material of the edge cover 21 must allow light to pass through and may be SiO, SiON, SiN, SiOC, SiC, HfSiON, ZrO, HfO, or LaO. The edge cover 21 preferably has a thickness in the range of 100 to 2000 nm. A thickness of 100 nm or less results in insufficient insulating properties, causing a leakage between the anode 13 and the cathode 20, high power consumption, and non-luminescence. A thickness of 2000 nm or more results in an increase in the film formation process time, low productivity, and wire breaking of an electrode in the edge cover 21.

The organic EL device 9 preferably has a microcavity structure (optical microcavity structure) due to an interference effect between a reflective electrode and a translucent electrode serving as the anode 13 and the cathode 20 or a microcavity structure due to a dielectric multilayer film. Such a structure can condense light from the organic EL device 9 in the front direction (impart directivity). This can reduce light that escapes to the surroundings and improve luminous efficiency at the front. This allows emission energy generated in the light-emitting layer 16 of the organic EL device 9 to be efficiently transferred to the fluorescent layers 7R, 7G, and 7B, thereby increasing front luminance. Furthermore, the interference effect allows the emission spectrum to be controlled to have a desired emission peak wavelength and half-width. Thus, the spectrum can be controlled to effectively excite fluorescent substances that emit their respective colored lights.

### (Advantages of First Embodiment)

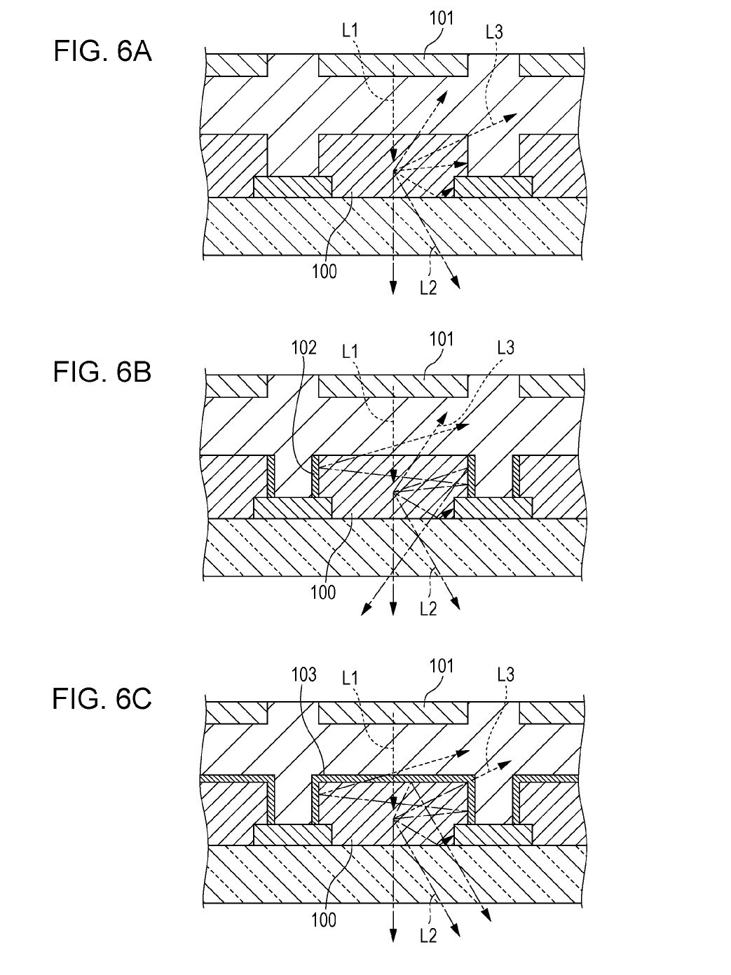

With such a structure, the fluorescence Lb generated in the fluorescent layers 7 is more efficiently emitted from the exit surface 7b than in the case of a fluorescent substrate having a known structure. This advantage will be described below with reference to FIG. 1 and FIGS. 6A to 6C.

As illustrated in FIG. 6A, when excitation light L1 (a dotted arrow) from a light source 101 enters a fluorescent layer 100, light from a fluorescent substance in the fluorescent layer 100 is isotropically emitted from the fluorescent layer 100 because of isotropic scattering caused by the fluorescent substance in the fluorescent layer 100. Thus, light L2 (an alternate long and short dashed arrow) emitted toward a light extraction surface (in a front direction) of the fluorescent layer 100 can be effectively emitted outward. Light L3 (a broken arrow) emitted in a side direction of the fluorescent layer 100 and toward a surface opposite the light extraction surface, however, is impossible to extract outward, causing loss in light emission. Light that can be actually extracted through the light extraction surface accounts for approximately 20% of the total light quantity.

In contrast, as illustrated in FIG. 6B, when only the side surfaces of the fluorescent layer 100 are covered with a reflective portion 102, such as a metal, part L2 of light generated in the fluorescent layer 100 travelling toward the side surfaces can be reflected by the reflective portion 102 and extracted outward. Light L3 travelling toward the back side (a light source side), however, cannot be extracted in the front direction. Thus, light cannot be efficiently extracted outward.

As illustrated in FIG. 6C, a transparent or translucent reflective multilayer film 103 that allows light having a peak wavelength of excitation light to pass through and reflects light having an emission peak wavelength of the fluorescent layer 100 may be formed on an excitation light incident surface (on the light source 101 side) and the side surfaces of the fluorescent layer 100. This allows the excitation light L1 to enter the fluorescent layer 100 and reflect part of light generated in the fluorescent layer 100.

The performance of the transparent or translucent reflective multilayer film 103, however, depends greatly on the light incident angle. Thus, the transparent or translucent reflective multilayer film 103 cannot fully exhibit its performance in the fluorescent layer 100 that emits light isotropically in all directions. A component passing through the transparent or translucent reflective multilayer film 103 can occur at a certain incident angle. Thus, light cannot be sufficiently extracted outward. In order to improve light extraction efficiency, therefore, it is important to reduce loss in excitation light entering the fluorescent layer and reduce loss in light in directions different from the light extraction direction of the fluorescent layer.

As compared with these structures, in the first embodiment, for example, as in the fluorescent substrate 2A of the display apparatus 1A illustrated in FIG. 1, the first reflective portions 11 are disposed on the side surfaces 7c of each of the fluorescent layers 7, and the second reflective portion 12 is disposed on the incident surface 7a. In the fluorescent substrate having such a structure, the first reflective portions 11 and the second reflective portion 12 can reflect portion of the fluorescence Lb that travels toward the incident surface 7a and the side surfaces 7c out of the fluorescence Lb that is isotropically emitted in all directions from the fluorescent layers 7 to efficiently direct the portion to the exit surface 7b, thereby improving luminous efficiency (improving luminance in the front direction).

An inorganic fluorescent substance can be used as the material of the fluorescent layers 7 to scatter light reflected by the first reflective portions 11 and the second reflective portion 12 of each of the fluorescent layers 7 utilizing its scattering effect, thereby directing the light to the exit surface 7b. Thus, the resulting display has excellent viewing angle characteristics.

A fluorescent substrate having such a structure can have high light extraction efficiency from a fluorescent substance and high conversion efficiency.

A display apparatus having such a structure can achieve excellent viewing angle characteristics and lower power consumption through the use of the fluorescent substrate.

Although the organic EL device 9 is used as a light source for emitting excitation light La in the first embodiment, the light source for excitation light is not limited to the organic EL device, provided that light having a wavelength that can excite a fluorescent substance can be emitted.

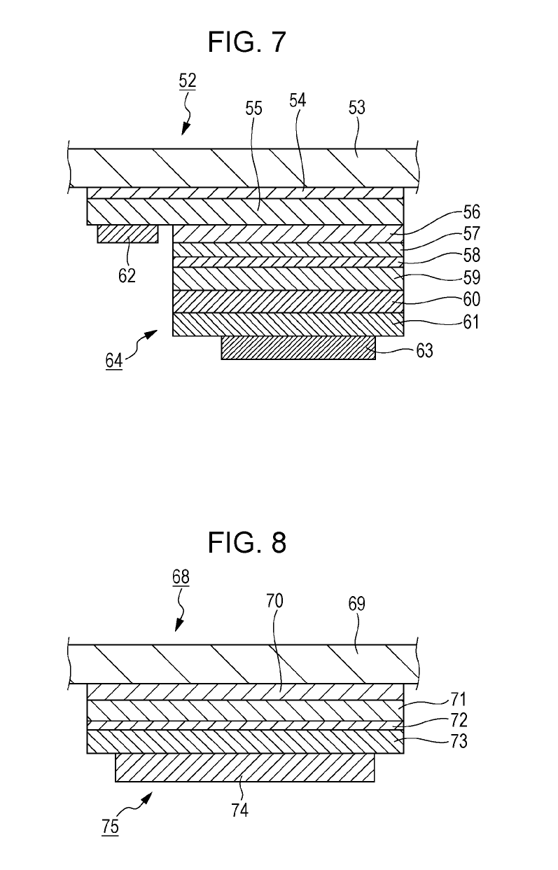

FIG. 7 is a cross-sectional view of a LED substrate 52 for use as a light source for emitting excitation light.

As illustrated in FIG. 7, the LED substrate 52 (light source) includes a first buffer layer 54, an n-type contact layer 55, a second n-type clad layer 56, a first n-type clad layer 57, an active layer 58, a first p-type clad layer 59, a second p-type clad layer 60, and a second buffer layer 61 on a substrate main body 53. The LED substrate 52 (light source) includes a LED 64, which includes a cathode 62 on the n-type contact layer 55 and an anode 63 on the second buffer layer 61. The LED substrate may be a known LED, for example, an ultraviolet-emitting inorganic LED or a blue-light-emitting inorganic LED and is not limited to the specific structure described above.

The components of the LED substrate 52 will be described in detail below.

The active layer 58 in the first embodiment emits light by recombination between an electron and a positive hole. The material of the active layer may be a known active layer material for LEDs. Such an active layer material, for example, an ultraviolet active layer material may be AlGaN, InAlN, or InₐAl_{b}Ga_{1-a-b}N (0≦a, 0≦b, a+b≦1). A blue active layer material may be In_{z}Ga_{1-z}N (0<z<1). The first embodiment is not limited to these materials.

The active layer 58 may have a single-quantum-well structure or a multiple-quantum-well structure. The active layer having a quantum well structure may be of n-type or p-type. The active layer 58 is preferably an undoped active layer (without the addition of an impurity), because interband emission reduces the half-width of emission wavelength and produces light emission having high color purity.

The active layer 58 may be doped with at least one of donor impurities and acceptor impurities. When the active layer doped with an impurity has the same crystallinity as an undoped active layer, doping with a donor impurity can further increase the interband emission intensity. Doping with an acceptor impurity can shift the peak wavelength to a wavelength approximately 0.5 eV lower than the peak wavelength of interband light emission but increases the half-width. Doping with both an acceptor impurity and a donor impurity can further increase the emission intensity as compared with the emission intensity of the active layer doped with the acceptor impurity alone. In particular, when the active layer is doped with an acceptor impurity, the conductive type of the active layer is preferably changed to an n-type by additional doping with a donor impurity, such as Si.

The n-type clad layers 56 and 57 in the first embodiment may be made of a known n-type clad layer material for LEDs and may have a monolayer or multilayer structure. When the n-type clad layers 56 and 57 are made of an n-type semiconductor having higher bandgap energy than the active layer 58, a potential barrier to positive holes is formed between the n-type clad layers 56 and 57 and the active layer 58. Thus, positive holes can be trapped in the active layer 58. For example, the n-type clad layers 56 and 57 may be formed of n-type InₓGa₁₋ₓN (0≦x<1). The first embodiment is not limited to these.

The p-type clad layers 59 and 60 in the first embodiment may be made of a known p-type clad layer material for LEDs and may have a monolayer or multilayer structure. When the p-type clad layers 59 and 60 are made of a p-type semiconductor having higher bandgap energy than the active layer 58, a potential barrier to electrons is formed between the p-type clad layers 59 and 60 and the active layer 58. Thus, electrons can be trapped in the active layer 58. For example, the p-type clad layers 59 and 60 may be formed of Al_{y}Ga_{1-y}N (0≦y≦1). The first embodiment is not limited to these.

The n-type contact layer 55 in the first embodiment may be made of a known contact layer material for LEDs. For example, the n-type contact layer 55 made of an n-type GaN may be formed as a layer that forms an electrode in contact with the n-type clad layers 56 and 57. A p-type contact layer made of a p-type GaN may be formed as a layer that forms an electrode in contact with the p-type clad layers 59 and 60. This contact layer is not necessary when the second n-type clad layer 56 and the second p-type clad layer 60 are formed of GaN. The second clad layer may be a contact layer.

These layers in the first embodiment may be formed by a known film formation process for LEDs. The first embodiment is not limited to this. For example, these layers may be formed on a substrate, for example, of sapphire (including C, A, and R planes), SiC (including 6H-SiC and 4H-SiC), spinel (MgAl₂O₄, particularly its (111) plane), ZnO, Si, or GaAs, or another oxide single-crystal substrate (such as NGO) by a vapor deposition method, such as metal-organic vapor phase epitaxy (MOVPE), molecular beam epitaxy (MBE), or hydride vapor phase epitaxy (HDVPE).

FIG. 8 is a cross-sectional view of an inorganic EL device substrate 68 for use as a light source for emitting excitation light.

As illustrated in FIG. 8, the inorganic EL device substrate (light source) includes an inorganic EL device 75, which includes a first electrode 70, a first dielectric layer 71, a light-emitting layer 72, a second dielectric layer 73, and a second electrode 74 on a substrate main body 69. The inorganic EL device 75 may be a known inorganic EL, for example, an ultraviolet-emitting inorganic EL or a blue-light-emitting inorganic EL and is not limited to the specific structure described above.

The components of the inorganic EL device substrate 68 will be described in detail below.

The substrate main body 69 may be the same as in the organic EL device substrate 4.

Examples of a transparent electrode material for the first electrode 70 and the second electrode 74 in the first embodiment include metals, such as aluminum (Al), gold (Au), platinum (Pt), and nickel (Ni), an oxide of indium (In) and tin (Sn) (ITO), an oxide of tin (Sn) (SnO₂), and an oxide of indium (In) and zinc (Zn) (IZO). The first embodiment is not limited to these materials. An electrode on the light extraction side is preferably a transparent electrode, such as ITO. An electrode disposed opposite the light extraction side is preferably a reflective portion, for example, made of aluminum.

The first electrode 70 and the second electrode 74 may be formed by a known method, such as an EB evaporation method, a sputtering method, an ion plating method, or a resistance-heating evaporation method, using the material described above. The first embodiment is not limited to these forming methods. If necessary, an electrode thus formed may be patterned by a photolithography method or a laser abrasion method, or a directly patterned electrode may be formed by a photolithography method or a laser abrasion method in combination with a shadow mask. The first electrode 70 and the second electrode 74 preferably have a thickness of 50 nm or more. A thickness of less than 50 nm may result in a high wire resistance and a high driving voltage.

The first dielectric layer 71 and the second dielectric layer 73 in the first embodiment may be made of a known dielectric material for use in inorganic ELs. Examples of such a dielectric material include tantalum pentoxide (Ta₂O₅), silicon oxide (SiO₂), silicon nitride (Si₃N₄), aluminum oxide (Al₂O₃), aluminum titanate (AlTiO₃), barium titanate (BaTiO₃), and strontium titanate (SrTiO₃). The first embodiment is not limited to these materials. The first dielectric layer 71 and the second dielectric layer 73 in the first embodiment may be made of one of the dielectric materials or may be a laminate of two or more materials. The dielectric layers 71 and 73 preferably have a thickness in the range of approximately 200 to 500 nm.

The light-emitting layer 72 in the first embodiment may be made of a light-emitting material for use in inorganic ELs. Such a light-emitting material, for example, an ultraviolet-emitting material may be ZnF₂:Gd, and a blue-light-emitting material may be BaAl₂S₄:Eu, CaAl₂S₄:Eu, ZnAl₂S₄:Eu, Ba₂SiS₄:Ce, ZnS:Tm, SrS:Ce, SrS:Cu, CaS:Pb, or (Ba,Mg)Al₂S₄:Eu. The first embodiment is not limited to these materials. The light-emitting layer 72 preferably has a thickness in the range of approximately 300 to 1000 nm.

The LED substrate 52 or the inorganic EL device substrate 68 may be used as a light source for a display apparatus in place of the organic EL substrate 4 of the display apparatus illustrated in FIG. 1 and can realize a display apparatus having high luminance in the front direction and excellent luminous efficiency.

The first embodiment exemplified the organic EL device, the LED, and the inorganic EL device as light sources. These structures preferably include a sealing film or a sealing substrate for sealing the light-emitting device, such as the organic EL device, the LED, and the inorganic EL device. The sealing film and the sealing substrate may be formed by a known sealing method using a known sealing material. More specifically, a resin may be applied to a surface of a substrate main body opposite a light source by a spin coating method, ODF, or a lamirate method to form a sealing film. Alternatively, an inorganic film, for example, of SiO, SiON, or SiN may be formed by a plasma CVD method, an ion plating method, an ion beam method, or a sputtering method, and a resin may be applied or bonded to the inorganic film by a spin coating method, ODF, or a lamirate method to form a sealing film.

Such a sealing film or a sealing substrate can prevent atmospheric oxygen or moisture to enter the light-emitting device and thereby improve the life of the light source. The light source and the fluorescent substrate may be bonded together with a common UV curable resin or thermosetting resin. Addition of a moisture absorbent, such as barium oxide, to a sealed inert gas can effectively reduce deterioration of the device due to moisture. The first embodiment is not limited to these components and forming methods. In the case that light is extracted from a surface opposite the substrate, the sealing film and the sealing substrate must be formed of an optically transparent material.

### Second Embodiment

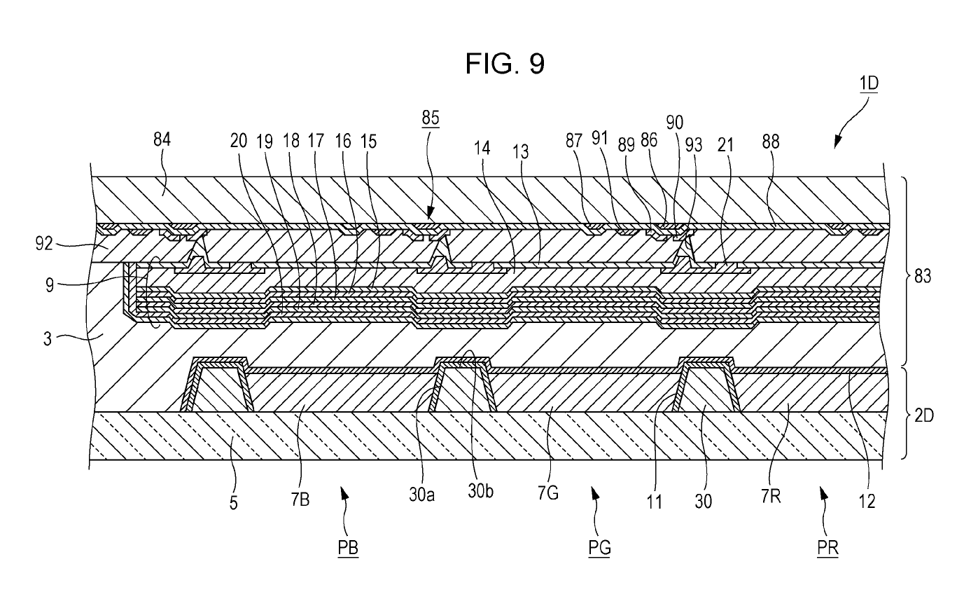

A fluorescent substrate and a display apparatus according to a second embodiment of the present invention will be described below with reference to FIGS. 9 to 11. Components common to the first embodiment and the second embodiment are denoted by the same reference numerals and will not be further described.

FIG. 9 is a general cross-sectional view of a display apparatus 1D according to the second embodiment and corresponds to FIG. 1 of the first embodiment. As illustrated in FIG. 9, the display apparatus 1D according to the second embodiment includes a fluorescent substrate 2D and an organic EL device substrate 83 (light source). The organic EL device substrate 83 is bonded to the fluorescent substrate 2D with a planarization film 3 interposed therebetween. The display apparatus 1D utilizes blue light emitted from the organic EL device substrate 83 as excitation light to excite a fluorescent substance of the fluorescent substrate 2D, thereby emitting fluorescence.

The fluorescent substrate 2D includes partitions 30, first reflective portions 11, fluorescent layers 7, and a second reflective portion 12. The partitions 30 form a matrix of openings 30a. The first reflective portions 11 are formed on surfaces (side surfaces 30a and top surfaces 30b) of the partitions 30. The fluorescent layers 7 are disposed in the openings 30a. The second reflective portion 12 is disposed over the entire surface of the fluorescent layers 7 and the partitions 30. The fluorescent layers 7 include fluorescent layers 7R, 7G, and 7B corresponding to a red color pixel PR, a green color pixel PG, and a blue color pixel PB.

The partitions 30 surrounding the fluorescent layers 7 are formed by patterning a resin material, such as a photosensitive polyimide resin, acrylic resin, metharyl resin, novolak resin, or epoxy resin, by photolithography. Alternatively, a non-photosensitive resin material may be directly patterned by screen printing to form a barrier. Alternatively, the material of the first reflective portions 11 may be used to form a barrier. In FIG. 9, the partitions 30 are formed by using a resin material. Although the partitions 30 are lattice-shaped, the partitions 30 may be striped.

The partitions 30 preferably have a higher top than the fluorescent layers 7. In other words, the length between a surface of a substrate main body 5 to the top of the partitions 30 is preferably greater than the thickness of the fluorescent layers 7. This can prevent the fluorescent layers 7 and the organic EL device substrate 83 from being damaged by contact with each other. Although the partitions 30 possibly come into contact with the organic EL device substrate 83, the partitions 30 are disposed in a region between pixels in a display area of the display apparatus. This region is not used for display and is unlikely to have adverse effects on display.

In the fluorescent substrate 2D having such a structure, a fluorescent component that escapes from the fluorescent layers 7 in a lateral direction can be directed in an emission direction, thereby improving light extraction efficiency from the fluorescent substance and conversion efficiency.

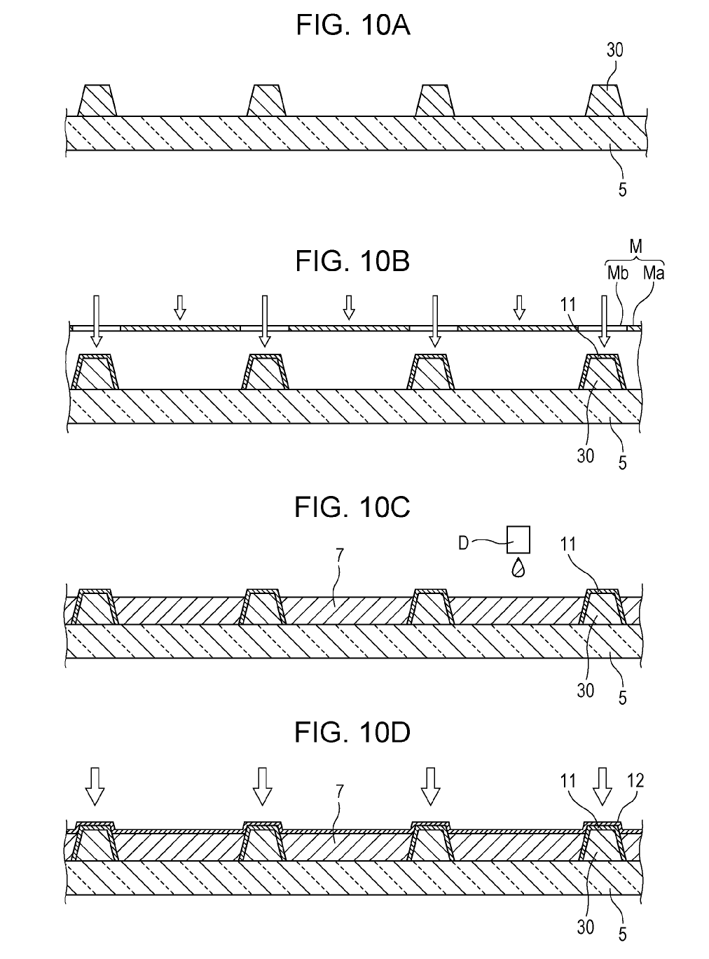

FIGS. 10A to 10D are process drawings of an example of a method for manufacturing the fluorescent substrate 2D.

As illustrated in FIG. 10A, a photosensitive epoxy resin precursor is applied to the substrate main body 5 and is subjected to mask patterning to form the forward tapered partitions 30. The fluorescent layers 7 having a desired shape and pattern can be formed between the partitions 30.

As illustrated in FIG. 10B, aluminum is evaporated by an EB evaporation method through a mask M that has shields Ma corresponding to the openings 30a surrounded by the partitions 30 and openings Mb corresponding to the partitions 30. Thus, a first reflective portion 11 is formed on the surface of each of the partitions 30. In consideration of adhesion between the partitions 30 and the first reflective portions 11, the first reflective portions 11 preferably have a thickness of several hundreds of nanometers.

As illustrated in FIG. 10C, a fluorescent layer forming coating liquid containing a fluorescent material and a resin material dissolved or dispersed in a solvent is applied to the openings 30a with a dispenser D and is dried to form the fluorescent layers 7.

As illustrated in FIG. 10D, six titanium oxide layers and six silicon oxide layers are alternately formed by an electron beam (EB) evaporation method to form the second reflective portion 12. Thus, the second reflective portion 12 is formed on the fluorescent layers 7 to complete the fluorescent substrate 2D.

### (Active-Matrix Drive Organic EL Device Substrate)

The organic EL device substrate 83 of the display apparatus 1D according to the second embodiment, which functions as a light source, will be described below with reference to FIG. 9.

The organic EL device substrate 83 includes an organic EL device 9 facing each of fluorescent layers 7R, 7G, and 7B. The organic EL device substrate 83 employs an active-matrix drive method using TFT for light irradiation of a red color pixel PR, a green color pixel PG, and a blue color pixel PB.

The organic EL device substrate 83 includes TFTs 85 on the substrate main body 84. More specifically, a gate electrode 86 and a gate line 87 are formed, and a gate-insulating film 88 is formed on the substrate main body 84 to cover the gate electrode 86 and the gate line 87. An active layer (not shown) is formed on the gate-insulating film 88, and a source electrode 89, a drain electrode 90, and a data line 91 are formed on the active layer. The source electrode 89, the drain electrode 90, and the data line 91 are covered with a planarization film 92.

The planarization film 92 may not be a monolayer structure and may be a combination of an interlayer insulating film and a planarization film. A contact hole 93 passes through the planarization film or the interlayer insulating film and reaches the drain electrode 90. An anode 13 of the organic EL device 9 is disposed on the planarization film 92. The anode 13 is electrically connected to the drain electrode 90 via the contact hole 93. The organic EL device 9 has the same structure as in the first embodiment.

The substrate main body 84 for active-matrix drive is preferably a substrate that is not melted at a temperature of 500° C. or less and causes no strain. A general metal substrate has a thermal expansion coefficient different from that of glass. Thus, it is difficult to form TFT on a metal substrate with a known production apparatus. A metal substrate made of an iron-nickel alloy having a linear expansion coefficient of 1×10⁻⁵/° C. or less that is comparable to the linear expansion coefficient of glass, however, can be used to inexpensively form TFT on a metal substrate with a known production apparatus. In the case of a plastic substrate having a very low heat resistant temperature, TFT formed on a glass substrate can be transferred to the plastic substrate to form the TFT on the plastic substrate. When light from an organic EL layer is extracted from a side opposite a substrate, there is no restrictions on the substrate. When light from an organic EL layer is extracted from a substrate, the substrate must be transparent or translucent.

The TFT 85 is formed on the substrate main body 84 before the formation of the organic EL device 9 and functions as a pixel switching device and an organic EL device driving device. The TFT 85 in the second embodiment may be a known TFT and may be formed using a known material, structure, and forming method. In the second embodiment, the TFT 85 may be substituted by a metal-insulator-metal (MIM) diode.

Examples of the material of the active layer of the TFT 85 include inorganic semiconductor materials, such as noncrystalline silicon (amorphous silicon), polycrystalline silicon (polysilicon), microcrystalline silicon, and cadmium selenide, oxide semiconductor materials, such as zinc oxide and indium oxide-gallium oxide-zinc oxide, and organic semiconductor materials, such as polythiophene derivatives, thiophene oligomers, poly(p-pherylenevinylene) derivatives, naphthacene, and pentacene. The TFT 85 may have a structure of a staggered, inversely staggered, top-gate, or coplanar type.

A method for forming the active layer of the TFT 85 may be (1) a method for ion-doping an amorphous silicon film formed by a plasma-enhanced chemical vapor deposition (PECVD) method with an impurity, (2) a method for forming amorphous silicon by a low-pressure chemical vapor deposition (LPCVD) method using silane (SiH₄) gas, crystallizing the amorphous silicon by a solid phase epitaxy method to produce polysilicon, and performing ion-doping by an ion implantation method, (3) a method for forming amorphous silicon by a LPCVD method using Si₂H₆ gas or a PECVD method using SiH₄ gas, annealing the amorphous silicon by a laser, such as an excimer laser, to crystallize the amorphous silicon, thereby producing polysilicon, and performing ion-doping (a low-temperature process), (4) a method for forming a polysilicon layer by a LPCVD or PECVD method, thermally oxidizing the polysilicon layer at 1000° C. or more to form a gate-insulating film, forming an n⁺ polysilicon gate electrode on the gate-insulating film, and then performing ion-doping (a high-temperature process), or (5) a method for forming an organic semiconductor material, for example, by an ink jet method, or (6) a method for producing a single-crystal film of an organic semiconductor material.

The gate-insulating film 88 of the TFT 85 in the second embodiment may be formed of a known material. For example, the material may be SiO₂ formed by a PECVD or LPCVD method or SiO₂ produced by thermal oxidation of a polysilicon film. The data line 91, the gate line 87, the source electrode 89, and the drain electrode 90 of the TFT 85 in the second embodiment may be formed using a known electrically conductive material, such as tantalum (Ta), aluminum (Al), or copper (Cu). Although the TFT 85 in the second embodiment may have the structures as described above, the second embodiment is not limited to these materials, structures, and forming methods.

The interlayer insulating film in the second embodiment may be formed using a known material, for example, an inorganic material, such as silicon oxide (SiO₂), silicon nitride (SiN or Si₃N₄), or tantalum oxide (TaO or Ta₂O₅), or an organic material, such as an acrylic resin or a resist material. A method for forming the interlayer insulating film may be a dry process, such as a chemical vapor deposition (CVD) method or a vacuum evaporation method, or a wet process, such as a spin coating method. If necessary, the interlayer insulating film may be patterned by a photolithography method.

When light from the organic EL device 9 is extracted from a side opposite the substrate main body 84, in order to prevent extraneous light entering the TFT 85 formed on the substrate main body 84 from changing the electrical characteristics of the TFT 85, a light-shielding insulating film having a light-shielding effect is preferably used. The interlayer insulating film and the light-shielding insulating film may be used in combination. Such a light-shielding interlayer insulating film may be one containing a pigment or dye, such as phthalocyanine or quinacrodone, dispersed in a polymer resin, such as a polyimide, a color resist, a black matrix material, or an inorganic insulating material, such as NiₓZn_{y}Fe₂O₄. However, the second embodiment is not limited to these materials and forming methods.

In the second embodiment, the TFT 85 and various electric wires and electrodes formed on the substrate main body 84 form surface asperities, which may cause defects of the organic EL device 9 (for example, a loss of the anode 13 or the cathode 20, wire breaking, a loss of the organic EL layer, a short circuit between the anode 13 and the cathode 20, or a decrease in withstand voltage). Thus, it is desirable to form a planarization film 92 on the interlayer insulating film in order to prevent these defects. The planarization film 92 in the second embodiment may be formed using a known material, for example, an inorganic material, such as silicon oxide, silicon nitride, or tantalum oxide, or an organic material, such as a polyimide, an acrylic resin, or a resist material. A method for forming the planarization film 92 may be a dry process, such as a CVD method or a vacuum evaporation method, or a wet process, such as a spin coating method. The second embodiment is not limited to these materials and forming methods. The planarization film 92 may have a monolayer structure or a multilayer structure.

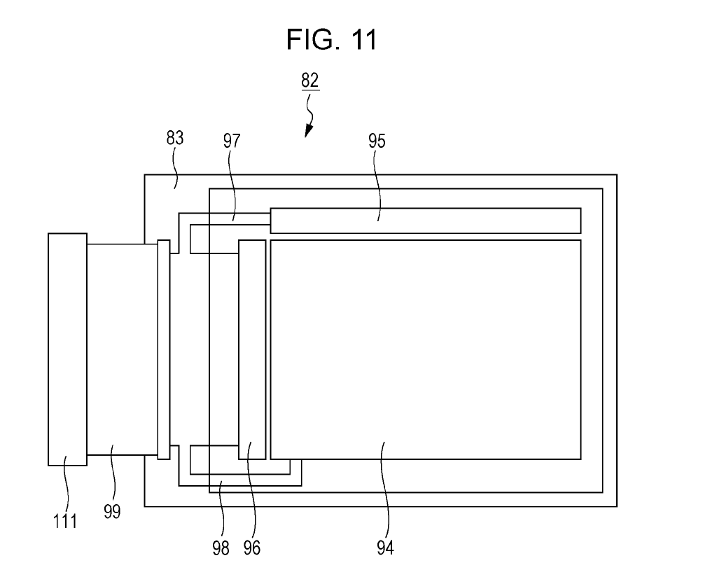

As illustrated in FIG. 11, the display apparatus 1D according to the second embodiment includes a pixel unit 94, a gate signal drive circuit 95, a data signal drive circuit 96, a signal wire 97, and a current supply line 98 on the organic EL device substrate 83, as well as a flexible printed wiring board 99 (FPC) and an external drive circuit 111 connected to the organic EL device substrate 83.

The organic EL device substrate 83 according to the second embodiment is electrically connected to the external drive circuit 111, which includes a scanning line electrode circuit, a data signal electrode circuit, and a power supply circuit, via the FPC 99, in order to drive the organic EL device 9. In the second embodiment, switching circuits, such as the TFT 85, are disposed in the pixel unit 94. Electric wires to be connected to the TFT 85, such as the data line 91 and the gate line 87, are connected to the data signal drive circuit 96 and the gate signal drive circuit 95 for driving the organic EL device 9. These drive circuits are connected to the external drive circuit 111 via the signal wire 97. A plurality of gate lines 87 and a plurality of data lines 91 are disposed in the pixel unit 94. The TFT 85 is disposed at an intersection of the gate line 87 and the data line 91.

The organic EL device 9 according to the second embodiment is driven by a voltage drive digital gradation system and includes two TFTs of a switching TFT and a driving TFT provided for each pixel. The driving TFT is electrically connected to the anode 13 of the organic EL device 9 via the contact hole 93 in the planarization layer 92. A condenser (not shown) for fixing the gate potential of the driving TFT is connected to the gate electrode of the driving TFT in each pixel. The second embodiment is not limited to this. The drive system may be the voltage drive digital gradation system or a current drive analog gradation system. The number of TFTs is not particularly limited. The organic EL device 9 may be driven with the two TFTs. Alternatively, in order to prevent variations in characteristics (mobility and threshold voltage) of the TFT 85, the organic EL device 9 may be driven with two or more TFTs including a compensation circuit in a pixel.

The second embodiment also has the advantage of the first embodiment that can realize a display apparatus having high luminance in the front direction and excellent luminous efficiency.

The second embodiment employs the active-matrix drive organic EL device substrate 83 and can therefore realize a display apparatus having excellent display quality. The active-matrix drive can increase the light emission time of the organic EL device 9 as compared with passive drive and thereby decrease the driving current required for desired luminance, thus reducing power consumption. Since light is extracted from a side opposite the organic EL device substrate 83 (a fluorescent substrate side), the emission region can be increased irrespective of the regions of TFTs and various electric wires, and the opening ratio of the pixels can be increased.

### Third Embodiment

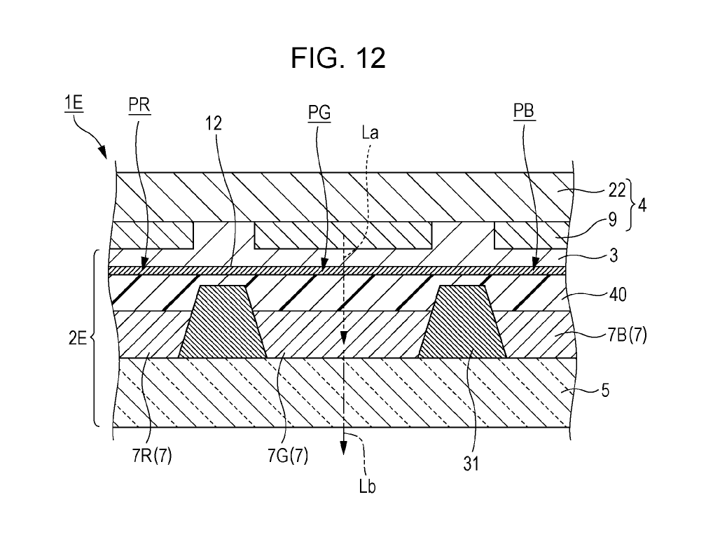

A fluorescent substrate and a display apparatus according to a third embodiment of the present invention will be described below with reference to FIGS. 12 to 14. Components common to the first to third embodiments are denoted by the same reference numerals and will not be further described.

FIG. 12 is a general cross-sectional view of a display apparatus according to the third embodiment and corresponds to FIG. 1. As illustrated in FIG. 12, a display apparatus 1E according to the third embodiment includes a fluorescent substrate 2E and an organic EL device substrate 4. The organic EL device substrate 4 is bonded to the fluorescent substrate 2E with a planarization film 3 interposed therebetween.

The fluorescent substrate 2E includes reflective partitions 31, fluorescent layers 7, a planarization layer 40, and a second reflective portion 12. The reflective partitions 31 are disposed on a substrate main body 5 and form a matrix of openings 31a. The fluorescent layers 7 are disposed in the openings 31a. The planarization layer 40 is disposed over the entire surface of the fluorescent layers 7 and the reflective partitions 31. The second reflective portion 12 is disposed over the entire surface of the planarization layer 40.

The fluorescent layers 7 include fluorescent layers 7R, 7G, and 7B corresponding to a red color pixel PR, a green color pixel PG, and a blue color pixel PB.

The reflective partitions 31 surrounding the fluorescent layers 7 may be formed of a reflective metal, such as aluminum, silver, gold, an aluminum-lithium alloy, an aluminum-neodymium alloy, or an aluminum-silicon alloy. The reflective partitions 31 may be formed by patterning a resin material containing dispersed fine particles of the reflective metal.

The reflective partitions 31 made of such a material can reflect fluorescence emitted in the fluorescent layers 7 in the same manner as in the first reflective portion 11 of the first and second embodiments. The first reflective portion 11 in FIG. 9 preferably has a thickness of several hundreds of nanometers in consideration of adhesion between the partitions 30 and the first reflective portion 11. The first reflective portion 11 having such a thickness, however, may insufficiently reflect visible light.

The reflective partitions 31 made of a light reflective material can have a sufficient thickness to reflect visible light.

The planarization layer 40 eliminates the surface asperities of the fluorescent layers 7 and a height difference between the fluorescent layers 7 and the reflective partitions 31 and forms a flat surface. The planarization layer 40 allows the second reflective portion 12 to be evenly formed on the flat surface. For example, when the second reflective portion 12 is formed by an evaporation method, the planarization layer 40 eliminates a portion in the shade of the reflective partitions 31 and thereby reduces the occurrence of defects in film formation.

The planarization layer 40 may be formed by applying a precursor or solution of a resin material, such as a photosensitive polyimide resin, acrylic resin, metharyl resin, novolak resin, or epoxy resin, to the entire surface by spin coating, and drying and curing the precursor or solution.

The second reflective portion 12 is disposed on the top surface of the planarization layer 40. Unlike the first and second embodiments, the second reflective portion 12 is spaced apart from the fluorescent layers 7. Even in the fluorescent substrate 2E having such a structure, a fluorescent component that escapes from the fluorescent layers 7 in a lateral direction can be directed in an emission direction, thereby improving light extraction efficiency from the fluorescent substance and conversion efficiency.

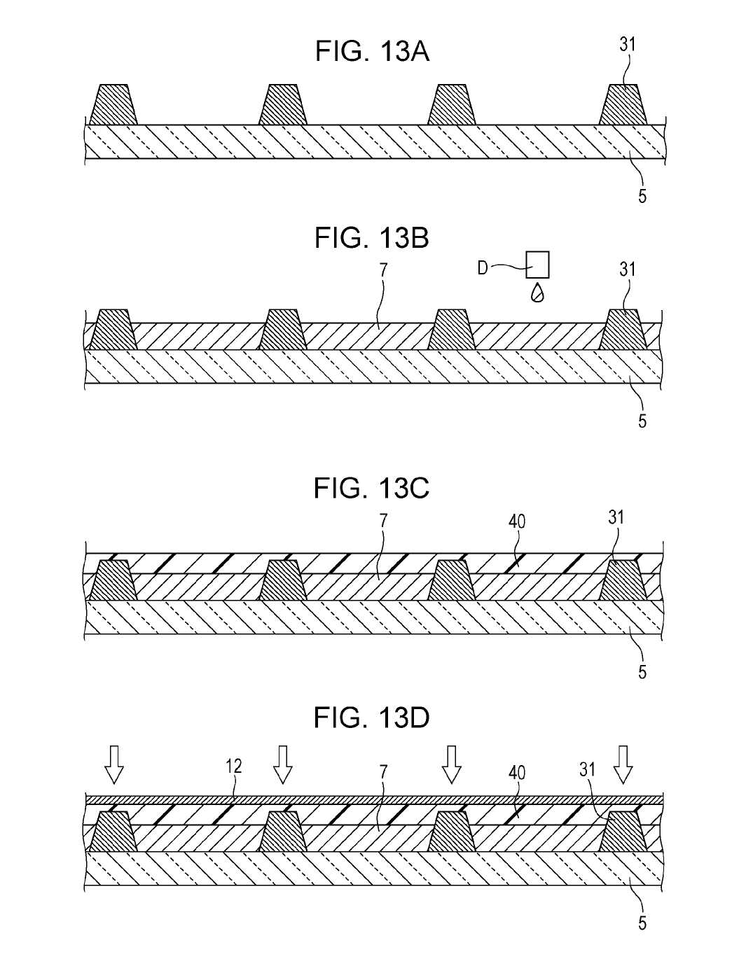

FIGS. 13A to 13D are process drawings of an example of a method for manufacturing the fluorescent substrate 2E.

As illustrated in FIG. 13A, a silver paste is applied to the substrate main body 5 by a screen printing method and is subjected to patterning to form the forward tapered reflective partitions 31.

As illustrated in FIG. 13B, a fluorescent layer forming coating liquid containing a fluorescent material and a resin material dissolved or dispersed in a solvent is applied to the openings 31a with a dispenser D and is dried to form the fluorescent layers 7.

As illustrated in FIG. 13C, an acrylic resin precursor is applied to the fluorescent layers 7 and the reflective partitions 31 over the entire surface of the substrate by a spin coating method and is cured by heating to form the planarization layer 40.

As illustrated in FIG. 13D, six titanium oxide layers and six silicon oxide layers are alternately formed by an electron beam (EB) evaporation method to form the second reflection portion 12 over the entire surface of the planarization layer 40. Thus, the fluorescent substrate 2E is completed.

The third embodiment also has the advantage of the first embodiment that can realize a display apparatus having high luminance in the front direction and excellent luminous efficiency. In the third embodiment, the manufacture of the fluorescent substrate 2E does not require mask patterning, permitting upsizing and facilitating the manufacture.

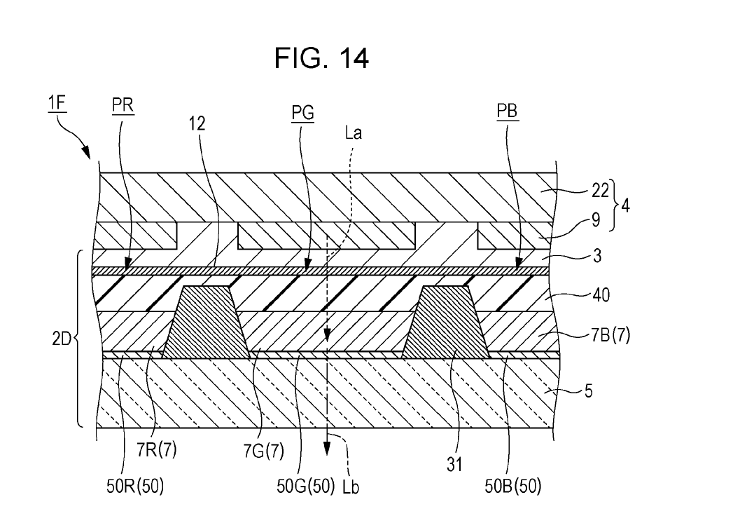

In the third embodiment and the first and second embodiments, a color filter may be disposed on the exit surface of the fluorescent layer, as in a modified example described below. FIG. 14 is a cross-sectional view of a display apparatus 1F according to a modified example of the third embodiment.

As illustrated in FIG. 14, the display apparatus 1F according to the modified example of the third embodiment includes color filters 50R, 50G, and 50B between a substrate main body 5 of a fluorescent substrate 2D and fluorescent layers 7R, 7G, and 7B of pixels. A red color pixel PR includes a red color filter 50R. A green color pixel PG includes a green color filter 50G. A blue color pixel PB includes a blue color filter 50B. The color filters 50R, 50G, and 50B may be known general color filters. The other components are as described in the third embodiment.

The modified example of the third embodiment also has the advantage of the first embodiment that can realize a display apparatus having high luminance in the front direction and excellent luminous efficiency.

In the modified example of the third embodiment, the color filters 50R, 50G, and 50B correspond to their respective pixels. This can increase the color purity of each of the red color pixel PR, the green color pixel PG, and the blue color pixel PB and extend the color reproduction range of the display apparatus 46.

The red color filter 50R under the red fluorescent layer 7R, the green color filter 50G under the green fluorescent layer 7G, and the blue color filter 50B under the blue fluorescent layer 7B absorb an excitation light component contained in extraneous light. This can reduce or prevent light emission of the fluorescent layers 7R, 7G, and 7B caused by extraneous light and reduce or prevent a decrease in contrast.

The blue color filter 50B, the green color filter 50G, and the red color filter 50R can prevent excitation light that is not absorbed by the fluorescent layers 7R, 7G, and 7B from leaking out. This can prevent deterioration of display color purity due to color mixing of light from the fluorescent layers 7R, 7G, and 7B and excitation light.

### Fourth Embodiment

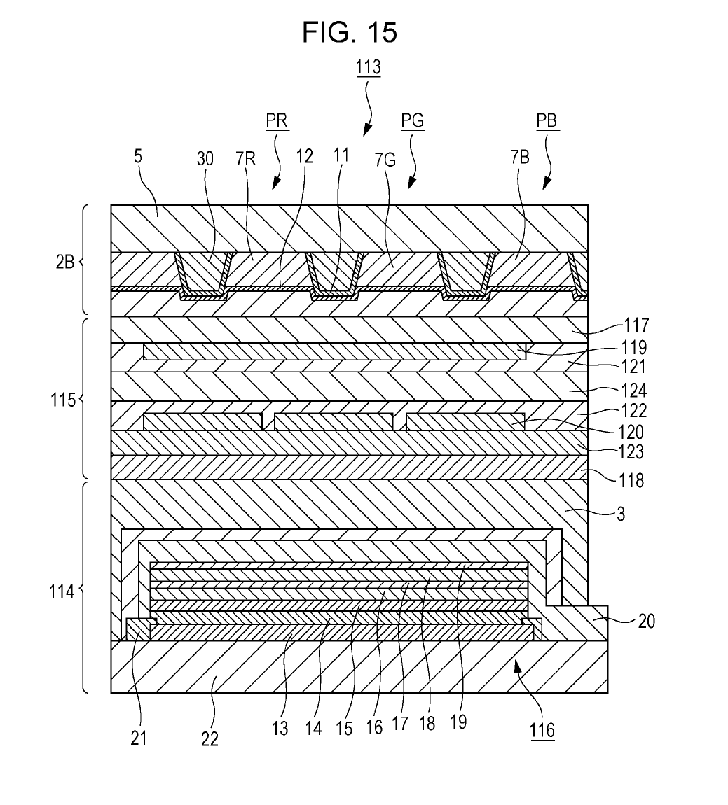

A fluorescent substrate and a display apparatus according to a fourth embodiment of the present invention will be described below with reference to FIG. 15. Components common to the first to fourth embodiments are denoted by the same reference numerals and will not be further described.

FIG. 15 is a cross-sectional view of a display apparatus 113 according to a fourth embodiment. The display apparatus 113 according to the fourth embodiment includes a liquid crystal device between a fluorescent substrate and a light source.

As illustrated in FIG. 15, the display apparatus 113 according to the fourth embodiment includes a fluorescent substrate 2B, an organic EL device substrate 114 (light source), and a liquid crystal device 115. The fluorescent substrate 2B has the same structure as in the second embodiment and will not be further described.

The organic EL device substrate 114 has the same layered structure as that illustrated in FIG. 5 in the first embodiment. In the first embodiment, a drive signal is individually sent to organic EL devices corresponding to respective pixels, and light emission from each of the organic EL devices is independently controlled. In the fourth embodiment, an organic EL device 116 is not provided for each pixel and functions as a planar light source common to all the pixels. The liquid crystal device 115 can control a voltage applied to a liquid crystal layer using a pair of electrodes in each pixel and control the transmittance of light from the entire surface of the organic EL device 116 in each pixel. Thus, the liquid crystal device 115 functions as an optical shutter for allowing light from the organic EL device substrate 114 to selectively pass through each pixel.

The liquid crystal device 115 according to the fourth embodiment may be a known liquid crystal device. For example, the liquid crystal device 115 includes a pair of polarizing plates 117 and 118, electrodes 119 and 120, alignment films 121 and 122, a substrate 123, and liquid crystals 124 disposed between the alignment films 121 and 122. An optical anisotropy layer may be disposed between a liquid crystal cell and one of the polarizing plates 117 and 118, or two optical anisotropy layers may be disposed between a liquid crystal cell and the polarizing plates 117 and 118. The type of the liquid crystal cell is not particularly limited and can be appropriately selected for each purpose, for example, a TN mode, a VA mode, an OCB mode, an IPS mode, or an ECB mode. The liquid crystal device 115 may be of passive drive or active drive using a switching element, such as TFT.

The fourth embodiment also has the advantage of the first embodiment that can realize a display apparatus having high luminance in the front direction and excellent luminous efficiency. In the fourth embodiment, a combination of pixel switching of the liquid crystal device 115 and the organic EL device substrate 114 functioning as a planar light source can further reduce power consumption.

### [Example of Electronic Equipment]

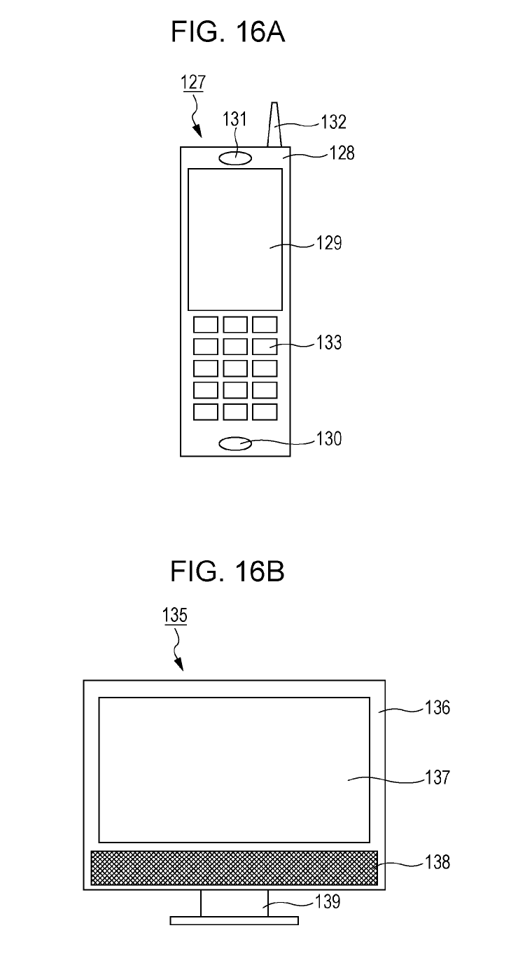

Examples of electronic equipment including a display apparatus according to one of the first to fourth embodiments include a mobile phone illustrated in FIG. 16A and a television set illustrated in FIG. 16B.

A mobile phone 127 illustrated in FIG. 16A includes a main body 128, a display screen 129, a sound input unit 130, a sound output unit 131, an antenna 132, and operation switches 133. The display screen 129 includes a display apparatus according to one of the first to fourth embodiments.

A television set 135 illustrated in FIG. 16B includes a main body cabinet 136, a display screen 137, a loudspeaker 138, and a support 139. The display screen 137 includes a display apparatus according to one of the first to fourth embodiments.

With a display apparatus according to one of the first to fourth embodiments, such electronic equipment can have excellent display quality and reduce power consumption.

### Fifth Embodiment

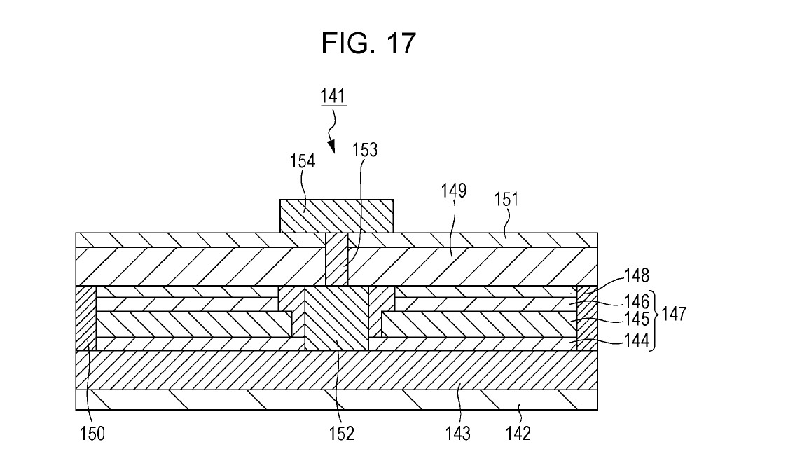

A lighting apparatus including a fluorescent substrate according to one of the first to fourth embodiments of the present invention will be described below with reference to FIG. 17.

As illustrated in FIG. 17, a lighting apparatus 141 according to a fifth embodiment includes an optical film 142, a fluorescent substrate 143, an organic EL device 147, a thermal diffusion sheet 148, a sealing substrate 149, a sealing resin 150, a radiator 151, a drive circuit 152, an electric wire 153, and a ceiling hunger 154. The organic EL device 147 includes an anode 144, an organic EL layer 145, and a cathode 146.

Since the fluorescent substrate 143 is a fluorescent substrate according to one of the first to fourth embodiments, the lighting apparatus is bright and can reduce power consumption.

The technical scope of the present invention is not limited to these embodiments, and various modifications may be made without departing from the gist of the present invention.

For example, the display apparatuses according to the first to fourth embodiments preferably include a polarizing plate on the light extraction side. The polarizing plate may be a combination of a known linearly polarizing plate and a λ/4 plate. Such a polarizing plate can prevent extraneous light reflection from an electrode of the display apparatus or extraneous light reflection from a surface of a substrate or a sealing substrate, thereby improving the contrast of the display apparatus. Specific description of the shape, number, arrangement, material, and forming method of components of a fluorescent substrate, a display apparatus, and a lighting apparatus is not limited to the first to fourth embodiments and may be appropriately modified.

### EXAMPLES

Although the present invention will be further described in the following examples, the present invention is not limited to these examples.

### Comparative Example 1

A glass sheet having a thickness of 0.7 mm was used as a substrate. The glass sheet was washed with water, was subjected to ultrasonic cleaning in pure water for 10 minutes, ultrasonic cleaning in acetone for 10 minutes, and isopropyl alcohol vapor cleaning for 5 minutes, and was dried at 100° C. for one hour.

15 g of ethanol and 0.22 g of γ-glycidoxypropyltriethoxysilane were added to 0.16 g of Aerosil having an average particle size of 5 nm and were stirred in an open system at room temperature for one hour. This mixture and 20 g of a green fluorescent substance CaO_{0.97}Mg_{0.03}:ZrO₃:Ho were triturated in a mortar, were heated in an oven at 70° C. for two hours, and were heated in an oven at 120° C. for two hours. Thus, surface-modified Ca_{0.97}Mg_{0.03}:ZrO₃:Ho was prepared.

A mixed solution of 30 g of poly(vinyl alcohol) dissolved in 300 g of a water/dimethyl sulfoxide=1/1 mixed solvent was then added to 10 g of the surface-modified Ca_{0.97}Mg_{0.03}:ZrO₃:Ho and was stirred with a dispersing apparatus. Thus, a coating liquid for forming a green fluorescent substance was prepared.

The coating liquid for forming a green fluorescent substance was applied to the substrate by a screen printing method at a width of 100 μm at intervals of 160 μm. The coating liquid was dried in a vacuum oven at 200° C. at 10 mmHg for 4 hours to form a green fluorescent layer having a thickness of 50 μm. Thus, a target fluorescent substrate according to Comparative Example 1 was completed.

### Example 1

A green fluorescent layer having a thickness of 50 μm was formed on a substrate in the same manner as in Comparative Example 1.

A silver paste was then applied by a dispenser method to the substrate in a region on which the fluorescent layer was not formed and was baked at 300° C. to form a first reflective portion. A first reflective portion was formed so as to cover 5 μm from an end of the fluorescent layer.

While the substrate was rotated, a silver film was formed on the fluorescent layer and the first reflective portion by a sputtering method to form a second reflective portion having a thickness of 25 nm. Thus, a target fluorescent substrate according to Example 1 was completed.

Luminance was measured in the fluorescent substrates according to Comparative Example 1 and Example 1 with a commercially available luminance meter (BM-7, manufactured by Topcon Technohouse Corp.). An ultraviolet light LED was used as an excitation light source. Luminance was measured using 380 nm excitation light at 25° C.

As a result, the fluorescent substrate according to Example 1 had luminance 2.5 times higher than that of the fluorescent substrate according to Comparative Example 1.

### Comparative Example 2

A photosensitive epoxy resin was applied to a substrate prepared in the same manner as in Comparative Example 1 to form forward tapered partitions each having a thickness of 60 μm in a 70 μm frame at intervals of 160 μm.

15 g of ethanol and 0.22 g of γ-glycidoxypropyltriethoxysilane were added to 0.16 g of Aerosil having an average particle size of 5 nm and were stirred in an open system at room temperature for one hour. This mixture and 20 g of a red fluorescent substance K₅Eu_{2.5}(WO₄)_{6.25} were triturated in a mortar, were heated in an oven at 70° C. for two hours, and were heated in an oven at 120° C. for two hours. Thus, a surface-modified K₅Eu_{2.5}(WO₄)_{6.25} was prepared.

A mixed solution of 30 g of poly(vinyl alcohol) dissolved in 300 g of a water/dimethyl sulfoxide=1/1 mixed solvent was then added to 10 g of the surface-modified K₅Eu_{2.5} (WO₄)_{6.25} and was stirred with a dispersing apparatus. Thus, a coating liquid for forming a red fluorescent substance was prepared.

The coating liquid for forming a red fluorescent substance was applied to regions surrounded by the partitions by a dispenser method. The coating liquid was dried in a vacuum oven at 200° C. at 10 mmHg for 4 hours to form a red fluorescent layer having a thickness of 50 μm, thus completing a target fluorescent substrate according to Comparative Example 2.

### Example 2

An aluminum layer having a thickness of 500 nm was formed by an EB evaporation method on partitions formed in the same manner as in Comparative Example 2.

A red fluorescent layer having a thickness of 50 nm was then formed between the partitions in the same manner as in Comparative Example 2.

Six layers of titanium oxide (TiO₂: refractive index=2.30) and six layers of silicon oxide (SiO₂: refractive index=1.47) were then alternately formed on the fluorescent layer and the partitions by an EB evaporation method to form a second reflective portion having a thickness of 2 μm. Thus, a target fluorescent substrate according to Example 2 was completed.

### Example 3

A silver paste was applied by a screen printing method to a substrate prepared in the same manner as in Comparative Example 1 to form forward tapered reflective partitions having a width of 70 μm and a thickness of 60 μm at intervals of 160 μm.

A red fluorescent layer having a thickness of 50 nm was then formed between the reflective partitions in the same manner as in Example 2.

An acrylic resin film having a thickness of 20 μm was then formed on the entire fluorescent substrate surface by a spin coating method and was heated at 120° C. for 30 minutes to form a planarization layer.

Six layers of titanium oxide (TiO₂: refractive index=2.30) and six layers of silicon oxide (SiO₂: refractive index=1.47) were then alternately formed on the planarization layer by an EB evaporation method to form a second reflective portion having a thickness of 2 μm. Thus, a target fluorescent substrate according to Example 3 was completed.

Luminance was measured in the fluorescent substrates according to Comparative Example 2 and Examples 2 and 3 with a commercially available luminance meter (BM-7, manufactured by Topcon Technohouse Corp.). A blue LED was used as an excitation light source. Luminance was measured using 450 nm excitation light at 25° C.

As a result, the fluorescent substrate according to Example 2 had luminance 2.1 times higher than that of the fluorescent substrate according to Comparative Example 2. The fluorescent substrate according to Example 3 had luminance 1.5 times higher than that of the fluorescent substrate according to Example 2 (3.2 times higher than that of the fluorescent substrate according to Comparative Example 2).

### Example 4

### Blue Organic EL+Fluorescent Substance System

### (Preparation of Fluorescent Substrate)

First, a silver paste was applied by a screen printing method to a glass substrate having a thickness of 0.7 mm to form forward tapered reflective partitions having a width of 70 μm and a thickness of 60 μm at intervals of 160 μm.

A coating liquid for forming a green fluorescent substance prepared in the same manner as in Comparative Example 1 was then applied to the substrate by a screen printing method. The coating liquid was dried in a vacuum oven at 200° C. at 10 mmHg for 4 hours to form a green fluorescent layer having a thickness of 50 μm.

Likewise, a red fluorescent layer having a thickness of 50 μm was formed using a coating liquid for forming a red fluorescent substance prepared in the same manner as in Comparative Example 2.

A mixed solution of 30 g of poly(vinyl alcohol) dissolved in 300 g of a water/dimethyl sulfoxide=1/1 mixed solvent was then added to 20 g of 1.5 μm silica particles (refractive index: 1.65) and was stirred with a dispersing apparatus. Thus, a coating liquid for forming a blue scattering layer was prepared.

The coating liquid for forming a blue scattering layer was applied to the substrate by a screen printing method. The coating liquid was dried in a vacuum oven at 200° C. at 10 mmHg for 4 hours to form a blue scattering layer having a thickness of 50 μm.

Six layers of titanium oxide (TiO₂: refractive index=2.30) and six layers of silicon oxide (SiO₂: refractive index=1.47) were then alternately formed on the fluorescent layer by an EB evaporation method to form a second reflective portion having a thickness of 2 μm. Thus, the red fluorescent layer, the green fluorescent layer, and the blue scattering layer were formed to complete a fluorescent substrate according to Example 4.

### (Preparation of Blue Organic EL Device)

A silver reflective electrode having a thickness of 100 nm was formed on a glass substrate having a thickness of 0.7 mm by a sputtering method. An indium-tin oxide (ITO) having a thickness of 20 nm was formed on the reflective electrode by a sputtering method to form a first electrode (the reflective electrode and an anode). The first electrode was patterned into stripes each having a width of 70 μm at intervals of 160 μm by a photolithography method.

A SiO₂ layer having a thickness of 200 nm was formed on the substrate by a sputtering method and was patterned by a known photolithography method so as to cover only edges of the first electrode, thus forming edge covers 23. A 5-μm portion of a short side of the first electrode from its end was covered with SiO₂. The glass sheet was washed with water, was then subjected to ultrasonic cleaning in pure water for 10 minutes, ultrasonic cleaning in acetone for 10 minutes, and isopropyl alcohol vapor cleaning for 5 minutes in this order, and was dried at 120° C. for one hour.

The substrate was fixed in a substrate holder in a resistance-heating evaporation apparatus. The pressure was decreased to 1×10⁻⁴ Pa or less. Organic layers including an organic light-emitting layer were formed by a resistance-heating evaporation method.

First, a hole-injection layer having a thickness of 100 nm was formed by the resistance-heating evaporation method using 1,1-bis(di-4-tolylaminophenyl)cyclohexane (TAPC) as a hole-injection material.

A hole-transport layer having a thickness of 40 nm was then formed by the resistance-heating evaporation method using N,N′-di-1-naphthyl-N,N′-diphenyl-1,1′-biphenyl-1,1′-biphenyl-4,4′-diamine (NPD) as a hole-transport material.

A blue organic light-emitting layer (thickness: 30 nm) was then formed on the hole-transport layer. The blue organic light-emitting layer was formed by co-evaporation of 1,4-bis-triphenylsilylbenzene (UGH-2) (a host material) and iridium (III) bis[(4,6-difluorophenyl)-pyridinato-N,C2]picolinate (Flrpic) (a blue phosphorescent dopant) at a vapor-deposition rate of 1.5 and 0.2 angstroms/second, respectively.

A hole-blocking layer (thickness: 10 nm) was then formed on the light-emitting layer using 2,9-dimethyl-4,7-diphenyl-1,10-phenanthroline (BCP).

An electron-transport layer (thickness: 30 nm) was then formed on the hole-blocking layer using tris(8-hydroxyquinoline)aluminum (Alq₃).

An electron-injection layer (thickness: 0.5 nm) was then formed on the electron-transport layer using lithium fluoride (LiF).

After that, a translucent electrode was formed as a second electrode.

First, the substrate was fixed in a metallization chamber. A shadow mask for forming the second electrode (a mask having openings such that the second electrode could be formed as stripes each having a width of 70 μm at intervals of 160 μm facing the stripes of the first electrode) and the substrate were aligned and fixed.

Magnesium and silver were co-evaporated on the electron-injection layer by a vacuum evaporation method at a vapor-deposition rate of 0.1 and 0.9 angstroms/second, respectively, to form a magnesium-silver layer having a desired pattern (thickness: 1 nm).

In order to enhance the interference effect and prevent voltage drop due to wire resistance in the second electrode, a silver film having a desired pattern (thickness: 19 nm) was formed at a vapor-deposition rate of 1 angstrom/second to form the second electrode.

The organic EL device has a microcavity effect (interference effect) between the reflective electrode (the first electrode) and the translucent electrode (the second electrode). This can increase front luminance and more efficiently transfer emission energy from the organic EL device to the fluorescent layers. Likewise, utilizing the microcavity effect, the emission peak was adjusted to 460 nm, and the half-width was adjusted to 50 nm.

An inorganic protective layer made of SiO₂ and having a size of 3 μm was then formed by a plasma CVD method using a shadow mask. The inorganic protective layer extended to sealing areas each having a width of 2 mm from the top, bottom, left, and right edges of a display screen. Thus, a substrate including the organic EL device was manufactured.

The organic EL device substrate and the fluorescent substrate thus manufactured were aligned using positioning markers disposed on the outside of the display screen. The fluorescent substrate had been coated with a thermosetting resin in advance. The organic EL device substrate was bonded to the fluorescent substrate with the thermosetting resin, which was cured at 80° C. for two hours. This bonding process was performed in dry air (water content: −80° C.) in order to prevent degradation of the organic EL due to water.

Finally, peripheral terminals were connected to an external power supply to complete an organic EL display apparatus.

When a desired electric current from the external power supply was applied to a desired striped electrode, using a blue-light-emitting organic EL as an excitation light source that could be switched as desired, blue light was converted into red and green light through the red fluorescent layer and the green fluorescent layer, respectively, thereby isotropically emitting red and green light. Furthermore, the blue scattering layer allowed isotropic blue-light emission, thereby allowing full-color displays. The resulting images were of high quality and had excellent viewing angle characteristics.

The organic EL display apparatus includes the reflective partitions and the second reflective portion around the fluorescent layers, as in Example 3. Thus, as in Example 3, the organic EL display apparatus can have higher luminance than known apparatuses having no reflective partition and no second reflective portion. In other words, the organic EL display apparatus can consume less electric power to have the luminance of known apparatuses, thus achieving lower power consumption.

### Example 5

### Active Drive Blue Organic EL+Fluorescent Substance System

A fluorescent substrate was manufactured in the same manner as in Example 4.

An amorphous silicon semiconductor film was formed on a 100×100 mm square glass substrate by a PECVD method. Subsequently, the amorphous silicon semiconductor film was subjected to crystallization treatment to form a polycrystalline silicon semiconductor film. The polycrystalline silicon semiconductor film was then patterned into a plurality of islands by a photolithography method. A gate-insulating film and a gate electrode layer were then formed in this order on the patterned polycrystalline silicon semiconductor layer and were patterned by a photolithography method.

The patterned polycrystalline silicon semiconductor film was then doped with an impurity element, such as phosphorus, to form source and drain regions, thus manufacturing a TFT device.

A planarization film was then formed. The planarization film included a silicon nitride film formed by a PECVD method and an acrylic resin layer formed with a spin coater in this order.

First, the silicon nitride film was formed and, together with the gate-insulating film, was etched to form a contact hole reaching the source and/or drain region, and a source line was then formed.

The acrylic resin layer was then formed. A contact hole reaching the drain region was formed at the same position as the contact hole passing through the gate-insulating film and the silicon nitride film in the drain region, thus completing an active-matrix substrate. The acrylic resin layer has a function as the planarization film.

A condenser for fixing the TFT gate potential is formed by inserting an insulating film, such as an interlayer insulating film, between a drain of a switching TFT and a source of a driving TFT.

A contact hole that passes through the planarization layer and electrically connects the driving TFT to each of a first electrode of a red-light-emitting organic EL device, a first electrode of a green-light-emitting organic EL device, and a first electrode of a blue-light-emitting organic EL device is formed on the active-matrix substrate.

A first electrode (anode) of each light emission pixel was formed by a sputtering method so as to be electrically connected to the contact hole passing through the planarization layer connected to the TFTs for driving the pixels. The first electrode was formed by stacking an aluminum (Al) film having a thickness of 150 nm and an indium oxide-zinc oxide (IZO, registered trademark) film having a thickness of 20 nm.

The first electrodes were patterned in shapes corresponding to their respective pixels by a known photolithography method. The first electrodes had an area of 70 μm×70 μm. A display screen formed on a 100 mm×100 mm square substrate had a size of 80 mm×80 mm and was provided with top, bottom, left, and right sealing areas each having a width of 2 mm. A pair of opposing sides (first sides) of the substrate had a 2-mm terminal lead on the outside of the sealing areas. A second side adjacent to the first sides and to be bent had a 2-mm terminal lead.

SiO₂ of the first electrode was then layered in a thickness of 200 nm by a sputtering method and was patterned to cover the edges of the first electrode by a known photolithography method. A 10-μm portion of four sides of the first electrode from its ends were covered with SiO₂ to form an edge cover.

The active substrate was washed by ultrasonic cleaning in acetone for 10 minutes and then UV-ozone cleaning for 30 minutes.

A steel manufacture injection layer, a steel manufacture transport layer, a blue organic light-emitting layer, a hole-blocking layer, an electron-transport layer, an electron-injection layer, a second electrode (a translucent electrode), and an inorganic protective layer were formed on the active substrate in the same manner as in Example 4, thus manufacturing an active drive organic EL device substrate.

The active drive organic EL device substrate and the fluorescent substrate thus manufactured were aligned using positioning markers disposed on the outside of the display screen. The fluorescent substrate had been coated with a thermosetting resin in advance. The organic EL device substrate was bonded to the fluorescent substrate with the thermosetting resin, which was cured at 80° C. for two hours. This bonding process was performed in dry air (water content: −80° C.) in order to prevent degradation of the organic EL due to water.

The substrate on the light extraction side is bonded to a polarizing plate to complete an active drive organic EL.

Finally, a terminal on the short side was connected to a power supply circuit through a source driver, and a terminal on the long side was connected to an external power supply through a gate driver. Thus, an active drive organic EL display apparatus according to Example 5 including a 80 mm×80 mm display screen was manufactured.

When a desired electric current from the external power supply was applied to each pixel, using a blue-light-emitting organic EL as an excitation light source that could be switched as desired, blue light was converted into red and green light through the red fluorescent layer and the green fluorescent layer, respectively, thereby isotropically emitting red and green light. Furthermore, the blue scattering layer allowed isotropic blue-light emission, thereby allowing full-color displays. The resulting images were of high quality and had excellent viewing angle characteristics.

The organic EL display apparatus includes the reflective partitions and the second reflective portion around the fluorescent layers, as in Example 3. Thus, as in Example 3, the organic EL display apparatus can have higher luminance than known apparatuses having no reflective partition and no second reflective portion. In other words, the organic EL display apparatus can consume less electric power to have the luminance of known apparatuses, thus achieving lower power consumption.

### Example 6

### Blue LED+Fluorescent Substance System

A fluorescent substrate was manufactured in the same manner as in Example 4.

Trimethylgallium (TMG) and NH₃ were used to grow a GaN buffer layer having a thickness of 60 nm on a C plane of a sapphire substrate placed in a reaction vessel at 550° C.

The temperature was then increased to 1050° C. SiH₄ gas as well as TMG and NH₃ were used to grow an n-type contact layer made of Si-doped n-type GaN and having a thickness of 5 μm.

Trimethylaluminum (TMA) was then added to the raw material gas. A second clad layer of a Si-doped n-type Al_{0.3}Ga_{0.7}N layer having a thickness of 0.2 μm was grown also at 1050° C.

The temperature was then decreased to 850° C. TMG, trimethylindium (TMI), NH₃, and SiH₄ were used to grow a first n-type clad layer made of Si-doped n-type In_{0.01}Ga_{0.99}N and having a thickness of 60 nm.

Subsequently, TMG, TMI, and NH₃ were used to grow an active layer made of undoped In_{0.05}Ga_{0.95}N and having a thickness of 5 nm at 850° C. Cyclopentadienyl magnesium (CPMg) as well as TMG, TMI, and NH₃ were used to grow a first p-type clad layer made of Mg-doped p-type In_{0.01}Ga_{0.99}N and having a thickness of 60 nm at 850° C.

The temperature was then increased to 1100° C. TMG, TMA, NH₃, and CPMg were used to grow a second p-type clad layer made of Mg-doped p-type Al_{0.3}Ga_{0.7}N and having a thickness of 150 nm.

Subsequently, TMG, NH₃, and CPMg were used to grow a p-type contact layer made of Mg-doped p-type GaN and having a thickness of 600 nm at 1100° C.

After the completion of these operations, the temperature was decreased to room temperature. The wafer was taken from the reaction vessel and was annealed at 720° C. to reduce the resistance of the p-type layers. A mask having a predetermined shape was formed on the top p-type contact layer. Etching was performed until the surface of the n-type contact layer was exposed.

After etching, a negative electrode made of titanium (Ti) and aluminum (Al) was formed on the n-type contact layer, and a positive electrode made of nickel (Ni) and gold (Au) was formed on the p-type contact layer. After the formation of the electrodes, the wafer was divided into 350 μm square chips. After that, a LED chip on a substrate on which an electric wire to be connected to a separately prepared external circuit was formed was fixed with a UV-cured resin and was electrically connected to the electric wire on the substrate, thus manufacturing a light source substrate including a blue LED.

The light source substrate and the fluorescent substrate were aligned using positioning markers disposed on the outside of the display screen. The fluorescent substrate had been coated with a thermosetting resin in advance. The organic EL device substrate was bonded to the fluorescent substrate with the thermosetting resin, which was cured at 80° C. for two hours. The bonding process was performed in dry air (water content: −80° C.)

Finally, peripheral terminals were connected to an external power supply to complete a LED display apparatus.

When a desired electric current from the external power supply was applied to a desired striped electrode, using the blue LED as an excitation light source that could be switched as desired, blue light was converted into red and green light through the red fluorescent layer and the green fluorescent layer, respectively, thereby isotropically emitting red and green light. Furthermore, the blue scattering layer allowed isotropic blue-light emission, thereby allowing full-color displays. The resulting images were of high quality and had excellent viewing angle characteristics.

Such a LED display apparatus also includes the reflective partitions and the second reflective portion around the fluorescent layers, as in Example 3. Thus, as in Example 3, the LED display apparatus can have higher luminance than known apparatuses having no reflective partition and no second reflective portion. In other words, the LED display apparatus can consume less electric power to have the luminance of known apparatuses, thus achieving lower power consumption.

These examples and comparative examples demonstrate the usefulness of the present invention.

### INDUSTRIAL APPLICABILITY

The present invention can be applied to a fluorescent substrate, a display apparatus, and a lighting apparatus that can improve fluorescence extraction efficiency after wavelength conversion and conversion efficiency.

### REFERENCE SIGNS LIST

1A to 1F, 113 display apparatus
2A to 2D fluorescent substrate
4, 114 organic EL device substrate (light source)
5 substrate main body
7 fluorescent layer
7a incident surface
7b exit surface
7c side surface
7R red fluorescent layer
7G green fluorescent layer
7B blue fluorescent layer
9, 116 organic EL device (light-emitting device)
11 first reflective portion (reflective portion)
12 second reflective portion (reflective portion)
30 partition
31 reflective partition (partition)
40 planarization layer
   52 LED substrate (light source)
   64 LED (light-emitting device)
   68 inorganic EL substrate (light source)
   75 inorganic EL device (light-emitting device)
   85 TFT (driver device)
   115 liquid crystal device
   141 lighting apparatus
   La excitation light
   Lb fluorescence
   PR red color pixel
   PG green color pixel
   PB blue color pixel

1. A fluorescent substrate, comprising:
a substrate;
a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, the incident surface including a first portion and a second portion, the excitation light passing through the second portion; and
reflective portions, which face the incident surface and side surfaces of the fluorescent layer in contact with the incident surface,
wherein the reflective portions include a first reflective portion that is disposed on the side surfaces and the first portion of the incident surface and reflects the excitation light and the fluorescence and
a second reflective portion disposed on the second portion of the incident surface the second reflective portion allowing at least light having a peak wavelength of the excitation light to pass through and reflecting at least light having a peak wavelength of the fluorescence.

2. The fluorescent substrate according to claim 1, wherein
the fluorescent layer includes a plurality of fluorescent layers each disposed in a predetermined region on the substrate,
a partition surrounding each of the plurality of fluorescent layers is disposed on a surface of the substrate, and
the first reflective portion is disposed on at least side surface of the partition.

3. The fluorescent substrate according to claim 2, wherein the partition is formed of the material of the first reflective portion.

4. The fluorescent substrate according to claim 2, wherein the length from the surface of the substrate to the top of the partition is larger than the thickness of the fluorescent layer.

5. The fluorescent substrate according to claim 1, wherein the first reflective portion is disposed on a side surface of the fluorescent layer.

6. The fluorescent substrate according to claim 1, wherein the second reflective portion allows 50% or more of the light having a peak wavelength of the excitation light to pass through.

7. The fluorescent substrate according to claim 1, further comprising a planarization layer on the incident surface of the fluorescent layer, wherein the second reflective portion is disposed on the planarization layer.

8. The fluorescent substrate according to claim 1, wherein the fluorescent layer contains an inorganic fluorescent substance.

9. The fluorescent substrate according to claim 1, wherein the second reflective portion is a dielectric multilayer film.

10. The fluorescent substrate according to claim 1, wherein the second reflective portion is a thin silver film.

11. A display apparatus, comprising a fluorescent substrate and a light source,
wherein the fluorescent substrate includes
a substrate,
a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, the incident surface including a first portion and a second portion, the excitation light passing through the second portion, and
reflective portions, which face the incident surface and side surfaces of the fluorescent layer in contact with the incident surface,
wherein the reflective portions include a first reflective portion that is disposed on the side surfaces and the first portion of the incident surface and reflects the excitation light and the fluorescence and
a second reflective portion disposed on the second portion of the incident surface, the second reflective portion allowing at least light having a peak wavelength of the excitation light to pass through and reflecting at least light having a peak wavelength of the fluorescence, and
the light source includes a light-emitting device for emitting ultraviolet light as excitation light with which the fluorescent layer is irradiated.

12. The display apparatus according to claim 11, further comprising:
a plurality of pixels, including a red color pixel for displaying an object with red light, a green color pixel for displaying an object with green light, and a blue color pixel for displaying an object with blue light,
wherein the fluorescent layer includes a red fluorescent layer for emitting red light utilizing the ultraviolet light as the excitation light in the red color pixel, a green fluorescent layer for emitting green light utilizing the ultraviolet light as the excitation light in the green color pixel, and a blue fluorescent layer for emitting blue light utilizing the ultraviolet light as the excitation light in the blue color pixel.

13. A display apparatus, comprising a fluorescent substrate and a light source,
wherein the fluorescent substrate includes
a substrate,
a fluorescent layer disposed on the substrate, the fluorescent layer emitting fluorescence owing to excitation light passing through an incident surface of the fluorescent layer facing the substrate and emitting the fluorescence through an exit surface of the fluorescent layer facing the incident surface, the incident surface including a first portion and a second portion, the excitation light passing through the second portion, and
reflective portions, which face the incident surface and side surfaces of the fluorescent layer in contact with the incident surface,
wherein the reflective portions include a first reflective portion that is disposed on the side surfaces and the first portion of the incident surface and reflects the excitation light and the fluorescence and
a second reflective portion disposed on the second portion of the incident surface, the second reflective portion allowing at least light having a peak wavelength of the excitation light to pass through and reflecting at least light having a peak wavelength of the fluorescence, and
the light source includes a light-emitting device for emitting blue light as excitation light with which the fluorescent layer is irradiated.

14. The display apparatus according to claim 13, further comprising:
a plurality of pixels, including a red color pixel for displaying an object with red light, a green color pixel for displaying an object with green light, and a blue color pixel for displaying an object with blue light,
wherein the fluorescent layer includes a red fluorescent layer for emitting red light utilizing the blue light as the excitation light in the red color pixel and a green fluorescent layer for emitting green light utilizing the blue light as the excitation light in the green color pixel, and
the blue color pixel includes a scattering layer for scattering the blue light.

15. The display apparatus according to claim 12 or 14, wherein the light source is an active-matrix drive light source, which includes a light-emitting device for each of the plurality of pixels and a driver device for driving the light-emitting device.

16. The display apparatus according to claim 15, wherein light is extracted from a surface of the substrate opposite the plurality of driver devices.

17. The display apparatus according to claim 11 or 13, wherein the light source is one of light-emitting diodes, organic electroluminescent devices, and inorganic electroluminescent devices.

18. The display apparatus according to claim 12 or 14, wherein the light source is a planar light source for emitting light through a light exit surface, and each of the pixels includes a liquid crystal device between the planar light source and the fluorescent substrate, the liquid crystal device controlling the transmittance of light emitted from the planar light source.

19. (canceled)
